(19) United States
(12) Patent Application Publication
(10) Pub. No.: US 2012/0227780 A1
(43) Pub. Date: Sep. 13, 2012

(54) THERMOELECTRIC CONVERSION MODULE AND METHOD OF MANUFACTURING SAME

(75) Inventors: Kazuaki Kurihara, Kawasaki (JP); Masatoshi Ishii, Kawasaki (JP); John Baniecki, Kawasaki (JP); Kazunori Yamanaka, Kawasaki (JP)

(73) Assignee: FUJITSU LIMITED, Kawasaki-shi (JP)

(21) Appl. No.: 13/477,267

(22) Filed: May 22, 2012

Related U.S. Application Data
(63) Continuation of application No. PCT/JP2010/069328, filed on Oct. 29, 2010.

(30) Foreign Application Priority Data
Nov. 27, 2009 (JP) 2009-270224
Feb. 19, 2010 (JP) 2010-035329

(51) Int. Cl. H01L 35/32; H01L 35/34

(52) U.S. Cl. 136/224; 136/201

(57) ABSTRACT

A thermoelectric conversion module includes an insulative substrate, a plurality of thermoelectric conversion material films disposed with a gap therebetween on a first surface of the insulative substrate and made of any one of an n-type thermoelectric conversion material and a p-type thermoelectric conversion material, a first electrode and a second electrode, formed away from each other on each of the thermoelectric conversion material films, a first thermal conduction member disposed on a side of the first surface of the insulative substrate and including a protruding portion in contact with the first, electrodes or the insulative substrate between the first electrodes, and a second thermal conduction member disposed on a side of a second surface of the insulative substrate and including a protruding portion in contact with the second surface of the insulative substrate at an area coinciding with the second electrodes.

### CROSS-REFERENCE TO RELATED APPLICATION

This application is a continuation of International Patent Application No. PCT/JP2010/069328 filed Oct. 29, 2010 and designated the U.S., the entire contents of which are incorporated herein by reference.

### FIELD

The embodiments discussed herein are related to a thermoelectric conversion module configured to convert thermal energy into electrical energy, and to a method of manufacturing the thermoelectric conversion module.

### BACKGROUND

In recent years, thermoelectric conversion elements have been drawing attention in the light of CO₂ reduction and environmental conservation. By using thermoelectric conversion elements, thermal energy, which has heretofore been wasted, may be converted into electrical energy and reused. Since a single thermoelectric conversion element provides low output voltage, a plurality of thermoelectric conversion elements are connected in series to form a thermoelectric conversion module in general.

General thermoelectric conversion modules have a structure in which two thermal conduction plates sandwich a number of semiconductor blocks made of a p-type thermoelectric conversion material (hereinafter, referred to as p-type semiconductor blocks) and a number of semiconductor blocks made of an n-type thermoelectric conversion material (hereinafter, referred to as n-type semiconductor blocks). The p-type semiconductor blocks and the n-type semiconductor blocks are arranged alternately in an in-plane direction of the thermal conduction plates and are connected in series by metal terminals disposed between the semiconductor blocks. Extraction electrodes are connected to both ends of the series-connected semiconductor blocks, respectively.

In a thermoelectric conversion module with such a structure, each thermoelectric conversion element is formed of one p-type semiconductor block, one n-type semiconductor block, and a terminal connecting these blocks. Meanwhile, a thermoelectric conversion element with such a structure is called a n-shaped thermoelectric conversion element, since the p-type semiconductor block, the n-type semiconductor block, and the terminal are arranged in the shape of n.

In the thermoelectric conversion module described above, giving a temperature difference between the two thermal conduction plates causes a potential difference inside each of the p-type semiconductor blocks and the n-type semiconductor blocks due to the Seebeck effect, and the resultant electric power may be extracted through the extraction electrodes. Such thermoelectric conversion modules have been expected to be applied as a wireless sensor node constituting a sensor network and as a power source for various kinds of electronic equipment using minute electric power.

Meanwhile, BiTe (bismutb-telluride) or PbTe (lead-telluride) has conventionally been used as a material for the thermoelectric conversion element. Te and Pb, however, are known as substances causing a large environmental load, and there has been a demand for thermoelectric conversion materials causing a small environment load. An oxide such as SrTiO₃ (strontium titanate: hereinafter, also referred to as “STO”) is one of the thermoelectric conversion materials causing a small environment load. For SrTiO₃, for example, a high Seebeck coefficient above 1 mV/K has been reported.

Patent Document 1: Japanese Examined Laid-open Utility Model Publication No. 06-40478

### Patent Document 2: Japanese Laid-open Patent Publication No. 2002-335021

Patent Document 3: Japanese Laid-open Patent Publication No. 2009-16812

Patent Document 4: Japanese Laid-open Patent Publication No. 09-110592

Patent Document 5: Japanese Laid-open Patent Publication No. 2006-61837

Non-Patent Document 1: Matthew L. Scullin, et. al, “Anomalously large measured thermoelectric power factor in Sr1-xLaxTiO3 thin films due to SrTiO3 substrate reduction”, Applied Physics Letters, 92, 202113 (2008)

It is conceivable to form a thermoelectric conversion element by using STO mentioned above. However, general, thermoelectric conversion elements are formed by combining a p-type semiconductor block and an n-type semiconductor block; then, while the n-type semiconductor block may be formed by using STO, there is at present no p-type thermoelectric conversion material comparable to STO. For this reason, if a thermoelectric conversion element is built by forming an n-type semiconductor block with STO and forming a p-type semiconductor block with a current p-type thermoelectric conversion material, a sufficient output is not obtained, because the contribution of the p-type semiconductor block is small.

### SUMMARY

According to an aspect of the embodiments, a thermoelectric conversion module includes: an insulative substrate; a plurality of thermoelectric conversion material films disposed with a gap therebetween on a first surface of the insulative substrate and made of any one of an n-type thermoelectric conversion material and a p-type thermoelectric conversion material; a first, electrode and a second electrode formed away from each other on each of the thermoelectric conversion material films; a first thermal conduction, member disposed on a side of the first surface of the insulative substrate and including a protruding portion in contact with the first electrodes or the insulative substrate between the first electrodes; and a second thermal conduction member disposed on a side of a second surface of the insulative substrate and including a protruding portion in contact with the second surface of the insulative substrate at an area coinciding with the second electrodes.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is an assembly diagram of a thermoelectric conversion module according to a first embodiment;

FIG. 2 is a plan view of a chief part of the thermoelectric conversion module according to the first embodiment;

FIG. 3 is a cross-sectional view of the thermoelectric conversion module taken along the I-I line of FIG. 2;

FIG. 4 is an equivalent circuit diagram of the thermoelectric conversion module according to the first embodiment;

FIGS. 5A to 5D are cross-sectional views illustrating a method of manufacturing the thermoelectric conversion module according to the first embodiment in a step-by-step manner;

FIG. 6 is a plan view of a substrate and thermoelectric conversion elements formed thereon in a thermoelectric conversion module according to modification 1 of the first embodiment;

FIG. 7 is a cross-sectional view of a thermoelectric conversion module according to modification 2 of the first embodiment;

FIG. 8 is a cross-sectional view of a thermoelectric conversion module according to modification 3 of the first embodiment;

FIG. 9 is a cross-sectional view of a thermoelectric conversion module according to modification 4 of the first embodiment;

FIG. 10 is a cross-sectional view of a thermoelectric conversion module according to modification 5 of the first embodiment;

FIG. 11 is a cross-sectional view of a thermoelectric conversion module according to modification 6 of the first embodiment;

FIG. 12 is a cross-sectional view of a thermoelectric conversion module according to modification 7 of the first embodiment;

FIG. 13 is a plan view of a substrate on which thermoelectric conversion elements of a thermoelectric conversion module according to a second embodiment are formed;

FIG. 14 is a cross-sectional view of the thermoelectric conversion module according to the second embodiment;

FIG. 15 is an equivalent circuit diagram of the thermoelectric conversion module according to the second embodiment;

FIG. 16 is a cross-sectional view of a thermoelectric conversion module according to modification 1 of the second embodiment;

FIG. 17 is a cross-sectional view of a thermoelectric conversion module according to modification 2 of the second embodiment;

FIG. 18 is a cross-sectional view of a thermoelectric conversion module according to modification 3 of the second embodiment;

FIG. 19 is a plan view of a substrate on which thermoelectric conversion elements of a thermoelectric conversion module according to a third embodiment are formed;

FIG. 20 is a cross-sectional view of the thermoelectric conversion module according to the third embodiment;

FIG. 21 is a plan view of a substrate on which thermoelectric conversion elements of a thermoelectric conversion module according to a fourth embodiment are formed;

FIG. 22 is a cross-sectional view of the thermoelectric conversion module according to the fourth embodiment;

FIG. 23 is a plan view of a substrate on which thermoelectric conversion elements of a thermoelectric conversion module according to a fifth embodiment are formed;

FIG. 24 is a cross-sectional view of the thermoelectric conversion module according to the fifth embodiment;

FIGS. 25A to 25K are cross-sectional views illustrating a method of manufacturing the thermoelectric conversion elements according to the fifth embodiment;

FIG. 26 is a plan view of a substrate on which thermoelectric conversion elements of a thermoelectric conversion module according to a sixth embodiment are formed;

FIG. 27 is a cross-sectional view of the thermoelectric conversion module according to the sixth embodiment; and

FTGS. 28A to 28F are cross-sectional views illustrating a method of manufacturing the thermoelectric conversion elements according to the sixth embodiment.

### DESCRIPTION OF EMBODIMENTS

Hereinafter, embodiments are described with reference to the accompanying drawings.

### 1. First Embodiment

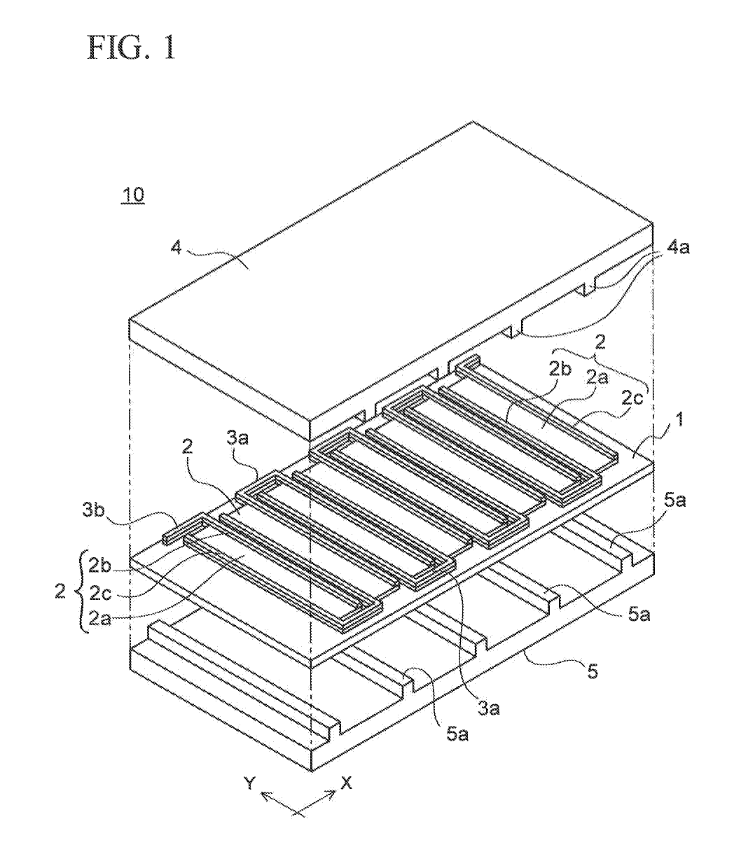

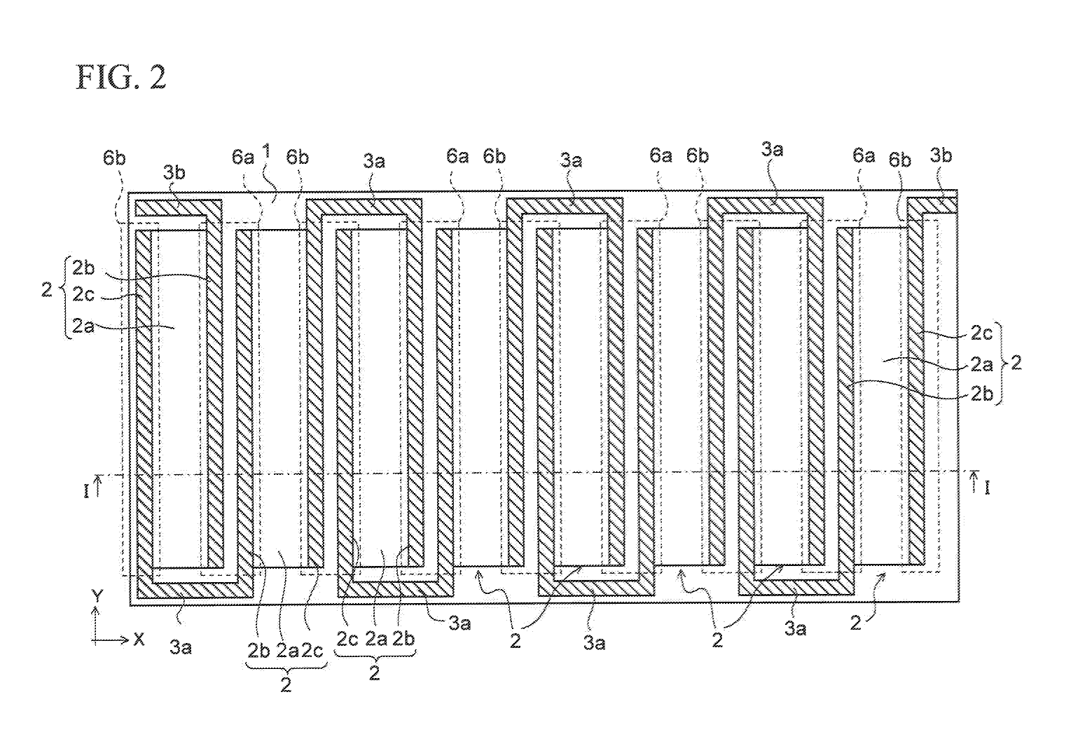

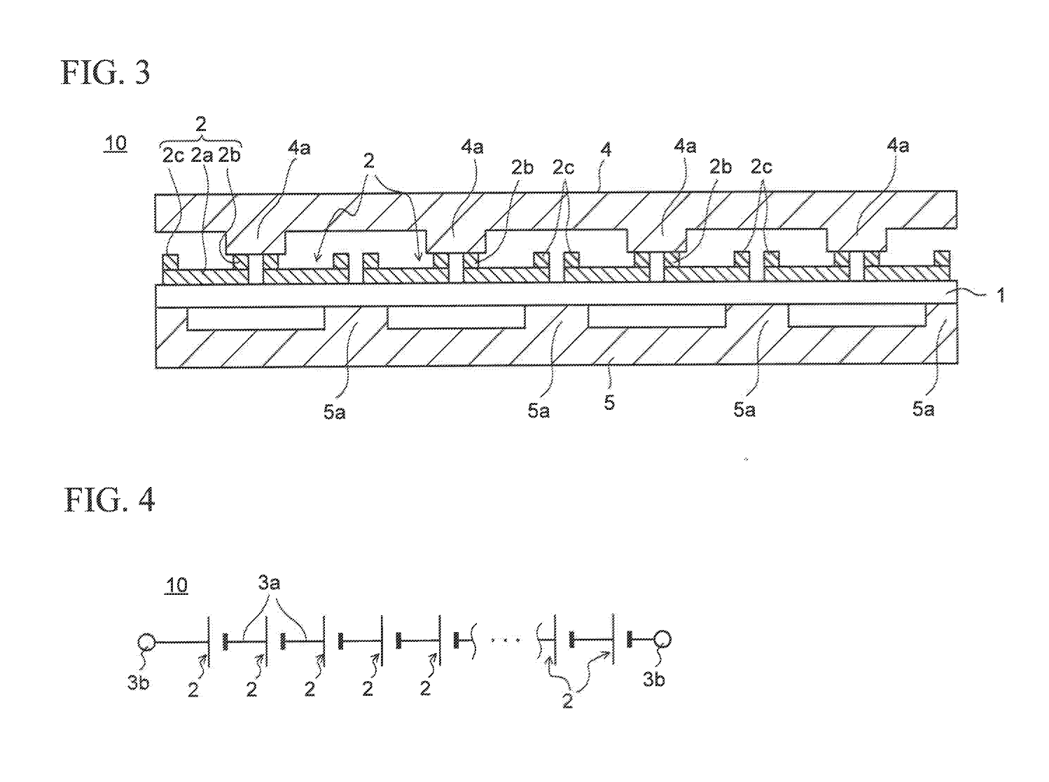

FIG. 1 is an assembly diagram of a thermoelectric conversion module according to a first embodiment. FIG. 2 is a plan view of a chief part of that same thermoelectric conversion module. FIG. 3 is a cross-sectional view of the thermoelectric conversion module taken along the I-I line of FIG. 2.

As depicted in FIGS. 1 and 3, a thermoelectric conversion module 10 according to this embodiment has a structure in which an insulative substrate 1 with thermoelectric conversion elements 2 formed thereon is sandwiched by two thermal conduction plates (thermal conduction members) 4 and 5. The insulative substrate 1 is made of single crystals of SrTiO₃ (strontium titanate), for example, and the thickness thereof is approximately 100 μm.

As depicted in FIG. 2, the plurality of thermoelectric conversion elements 2 are disposed, on the insulative substrate 1 at a fixed pitch in an in-plane direction. Each thermoelectric conversion element 2 includes a thermoelectric conversion material film 2a formed in a rectangular shape, and a high-temperature side electrode 2b and a low-temperature side electrode 2c formed respectively along two opposite sides of the thermoelectric conversion, material film 2a. The thermoelectric conversion material film 2a is made of SrTiO₃ doped with La (lanthanum), for example, (hereinafter, also referred to as “La-STO”) and the thickness thereof is approximately 15 nm. Moreover, the lengths of the thermoelectric conversion material film 2a in an X direction (widthwise direction) and a Y direction (lengthwise direction) in FIG. 2 are approximately 170 μm and approximately 15 mm, respectively. Further, in this embodiment, the gap between the adjacent thermoelectric conversion elements 2 is approximately 30 μm.

Each of the electrodes 2b and 2c of each thermoelectric conversion element 2 is formed of a low-resistance, conductive material such as Cu (copper), for example, and the width thereof is 30 μm, for example. As depicted in FIG. 2, electrodes of the same type (high-temperature side electrode 2b or low-temperature side electrode 2c) are disposed respectively along the facing sides of the adjacent thermoelectric conversion elements 2. Moreover, the high-temperature side electrode 2b of each thermoelectric conversion element 2 is connected to the low-temperature side electrode 2c of the thermoelectric conversion element 2 located adjacently on one side through a wiring 3a, while the low-temperature side electrode 2c is connected to the high-temperature side electrode 2b of the thermoelectric conversion element 2 located adjacently on the other side through a wiring 3a. In the thermoelectric conversion module 10 of FIG. 2, however, the high-temperature side electrode 2b of the thermoelectric conversion element 2 disposed at the left end and the low-temperature side electrode 2c of the thermoelectric conversion element 2 disposed at the right end are connected respectively to extraction electrodes 3b through which to extract electric power.

FIG. 4 is an equivalent circuit diagram of the thermoelectric conversion module 10 according to this embodiment. As depicted in this FIG. 4, the thermoelectric conversion module 10 according to this embodiment has a structure in which the plurality of thermoelectric conversion elements 2 are connected in series between the pair of extraction electrodes 3b.

The thermal conduction plates 4 and 5 are each formed of an aluminum plate with its surface subjected to insulating treatment, for example. As depicted in FIG. 3, the thermal conduction plate 4 has protruding portions 4a in contact with the high-temperature side electrodes 2b of the thermoelectric conversion elements 2, and the thermal conduction plate 5 has protruding portions 5a in contact with the back surface of the substrate 1 at areas coinciding with the low-temperature side electrodes 2c of the thermoelectric conversion elements 2. In FIG. 2, reference numerals 6a denote the areas for the protruding portions 4a of the thermal conduction plate 4 to contact, and reference numerals 6b denote the areas for the protruding portions 5a of the thermal conduction plate 5 to contact. In this embodiment, the protruding portions 4a of the thermal conduction plate 4 are in thermal contact with the thermoelectric conversion material films 2a near the high-temperature side electrodes 2b through the high-temperature side electrodes 2b. The protruding portions 5a of the thermal conduction plate 5 are in thermal contact with the thermoelectric conversion material film 2a near the low-temperature side electrodes 2c through the insulative substrate 1.

In the thermoelectric conversion module 10 according to this embodiment configured as above, the thermal conduction plate 4 is disposed on the high-temperature side, and the thermal conduction plate 5 is disposed on the low-temperature side. In this way, heat is transferred to the thermoelectric conversion material films 2a of the thermoelectric conversion elements 2 through the protruding portions 4a and 5a of the thermal conduction plates 4 and 5 and the insulative substrate 1, thereby causing a temperature difference in each thermoelectric conversion material film 2a in the in-plane direction (in a direction from the high-temperature side electrode 2b toward the low-temperature side electrode 2c). This in turn induces the transfer of charges (carriers) between the high-temperature side and the low-temperature side of the thermoelectric conversion material film 2a. Specifically, voltage is generated by the Seebeck effect between the high-temperature side electrode 2b and the low-temperature side electrode 2c of the thermoelectric conversion element 2. Although the voltage generated by a single, thermoelectric, conversion element 2 is low, relatively high voltage may be extracted through the extraction electrodes 3b since many thermoelectric conversion elements 2 are connected in series between the thermal conduction plates 4 and 5.

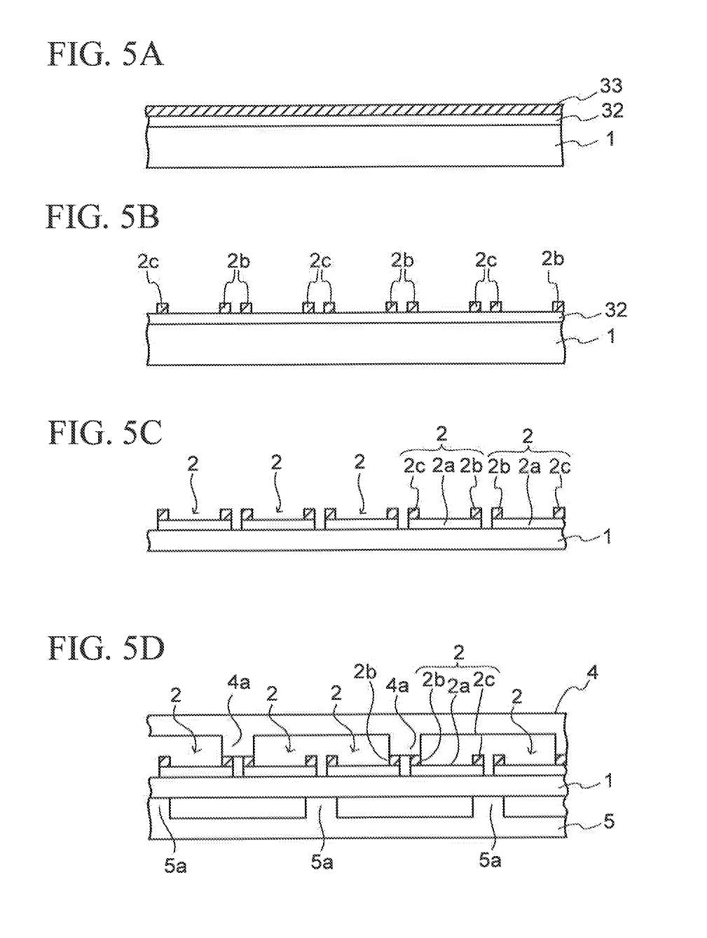

FIGS. 5A to 5D are cross-sectional views illustrating a method of manufacturing the thermoelectric conversion module according to the first embodiment in a step-by-step manner.

First, as depicted in FIG. 5A, a monocrystalline SrTiO₃ substrate 1 with a surface orientation (100) is prepared. Then, SrTiO₃ doped with La by 3 at % (La-STO) is deposited (epitaxially grown) to a thickness of approximately 15 nm on this substrate 1 by sputtering to form an n-type thermoelectric conversion material film 32. Thereafter, copper (Cu) is deposited to a thickness of approximately 1 μm on the thermoelectric conversion material film 32 by sputtering to form a plating seed layer 33.

Note that in this embodiment, the thermoelectric conversion material film 32 is made of single crystals of La-STO. The thermoelectric conversion material film 32 exhibits better thermoelectric conversion properties when monocrystalline, but may be polycrystalline.

Next, steps to obtain the structure in FIG. 5B are described. First, a resist film (not depicted) with openings formed in desired patterns (the patterns of the high-temperature side electrodes 2b, the low-temperature side electrodes 2c, the wirings 3a, and the extraction electrodes 3b) is formed on the plating seed layer 33. Then, copper (Cu) is formed to a thickness of approximately 20 μm on the plating seed layer 33 inside the openings by electroplating, for example, to form the high-temperature side electrodes 2b, the low-temperature side electrodes 2c, the wirings 3a (not depicted in FIGS. 5B to 5D), and the extraction electrodes 3b (not depicted in FIGS. 5B to 5D). Note that the high-temperature side electrodes 2b, the low-temperature side electrodes 2c, the wirings 3a, and the extraction electrodes 3b may be formed of a different low-resistance, conductive material, for example, Ag (silver), Au (gold), or Al (aluminum).

Thereafter, the resist film is removed. Then, by using an aqueous ferric chloride solution as etchant, for example, the portions of the plating seed layer 33 which are not covered with the high-temperature side electrodes 2b, the low-temperature side electrodes 2c, the wirings 3a, and the extraction electrodes 3b are removed to electrically isolate the electrodes 2b and 2c, the wirings 3a, and the extraction electrodes 3b from each other. As a result, the structure in FIG. 5B is obtained.

Next, a photoresist film (not depicted) designed to cover desired areas (the areas in which to form the thermoelectric conversion elements) is formed on the substrate 1 by photolithography. Then, with this photoresist film as a mask, the thermoelectric conversion material film 32 is etched to form the plurality of thermoelectric conversion elements 2 each including a thermoelectric conversion material film 2a, a high-temperature side electrode 2b, and a low-temperature side electrode 2c as depicted in FIG. 5C. Note that diluted nitric acid, for example, is used for the etching of the thermoelectric conversion material (La-STO) film 32. The thermoelectric conversion material film 32 may be etched by physical etching such as ion milling, instead of the chemical etching using dilute nitric acid or the like.

Next, the substrate 1 is cut into a desired size. Then, the back surface of the substrate 1 is polished until the thickness reaches 100 μm, for example. Thereafter, extraction wirings are soldered to the extraction electrodes 3b of the substrate 1. Subsequently, as depicted in FIG. 5D, the thermal conduction plates 4 and 5 are attached to both sides of the substrate 1 in the thickness direction. The thermal conduction plates 4 and 5 are each obtained by pressing an aluminum plate, for example, to form the protruding portions 4a and 5a, and thereafter anodizing the surface to give insulative properties thereto. The protruding portions 4a and 5a may be formed by cutting or by some other method. As a result, the thermoelectric conversion module 10 according to this embodiment is completed.

Description is given below of the result of an observation on the properties of a thermoelectric conversion module 10 which is actually manufactured by using the method described above.

By using the method described above, a thermoelectric conversion module 10 having a structure in which 70 thermoelectric conversion elements 2 are connected in series on a SrTiO₃ substrate 1 of a thickness of approximately 100 μm is formed. The thermoelectric conversion module 10 is of a substantially square shape with each side being approximately 15-mm long, and the thickness thereof is approximately 1 mm. Each thermoelectric conversion element 2 includes the thermoelectric conversion material film 2a, the high-temperature side electrode 2b, and the low-temperature side electrode 2c. The thickness of the thermoelectric conversion material film 2a is approximately 15 nm, and the lengths thereof in the X direction (widthwise direction) and the Y direction (lengthwise direction) in FIG. 2 are approximately 170 μm and approximately 15 mm, respectively. Moreover, the two thermal conduction plates 4 and 5 are formed of aluminum, and their surfaces are subjected to anodic treatment.

When a temperature difference of 10° C. is given between the two thermal conduction plates 4 and 5, the open-circuit voltage and the maximum output of this thermoelectric conversion module 10 are 0.6 V and 0.25 mW, respectively.

Meanwhile, in this embodiment, each thermoelectric conversion material film 2a is formed of a material low in electrical conductivity (i.e. high in resistivity) such as La-STO. If the thermoelectric conversion material film is formed of a material high in electrical conductivity (i.e. low in resistivity) such as BiTe used in conventional, n-shaped thermoelectric conversion elements, the electric power generated by the thermoelectric conversion element is consumed by the wiring, which is not practical. The following describes this in detail.

When the electrical conductivity of La-STO is 2000 S/cm, and a thermoelectric conversion material film 2a (see FIGS. 2 and 3) formed of this La-STO has a length of 200 μm in the widthwise direction, a length of 15 mm in the lengthwise direction, and a thickness of 15 nm, the resistance of this thermoelectric conversion material film 2a is approximately 5.6 Ω. On the other hand, the resistance of a wiring (copper wiring) 3a connecting two thermoelectric conversion elements 2 is approximately 0.4 Ω when its width, length, and thickness are 30 μm, 200 μm, and 20 μm, respectively. Hence, the resistance of the wiring 3a is 1/10 or below of the internal resistance of the thermoelectric conversion element 2, which makes the proportion of the power loss by the wiring small.

In contrast, when the electrical conductivity of BiTe is 50000 S/cm, and a thermoelectric conversion material film formed of this BiTe has a length of 200 μm in the widthwise direction, a length of 15 mm in the lengthwise direction, and a thickness of 15 nm, the resistance of this thermoelectric conversion material film is approximately 0.03 Ω. Hence, the resistance of the wiring is higher than the internal resistance of the thermoelectric conversion element, so that a large portion of the electric power generated by the thermoelectric conversion element is consumed by the wiring.

The above fact indicates the importance of forming the thermoelectric conversion material film of a material low in electrical conductivity. In this embodiment, it is preferable to form the thermoelectric conversion material film of a thermoelectric conversion material with electrical conductivity within a range from 1000 S/cm to 10000 S/cm. With electrical conductivity of 1000 S/cm or below, the power output would be small.

Besides La-STO mentioned above, SrTiO₃ doped with Nb (niobium) (Nb-STO) may be used as the thermoelectric conversion material usable in this embodiment. SrTiO₃ doped with conductive impurities such as La or Nb has a perovskite structure and exhibits a high Seebeck coefficient when formed into a thin film. Thus, SrTiO₃ doped with conductive impurities such as La or Nb is preferable as the material for the thermoelectric conversion material film of the thermoelectric conversion module of this embodiment. In addition to these, it may be possible to use an n-type oxide semiconductor material mainly containing ZnO, TiO₂, LaNiO₃, or the like, or a p-type oxide semiconductor material mainly containing LaCrO₃, NaCoO₂, Ca₃Co₄O₃, or the like, as the thermoelectric conversion material for the thermoelectric conversion module 10 of this embodiment.

The thermoelectric conversion module 10 of this embodiment uses La-STO high in Seebeck coefficient for the thermoelectric conversion material film. Thus, the thermoelectric conversion, module according to this embodiment may increase the output per unit area, as compared to thermoelectric conversion modules using a conventional thermoelectric conversion element including an n-type semiconductor and a p-type semiconductor (n-shaped thermoelectric conversion element). In addition, in this embodiment, the thermoelectric conversion element is formed with use of a film forming technique and a microfabrication technique using photolithography. This brings about an advantage that the thermoelectric conversion module may be manufactured more easily than a conventional method in which semiconductor blocks are cut out of a semiconductor substrate and arranged.

Modifications of the first embodiment are described below.

### Modification 1

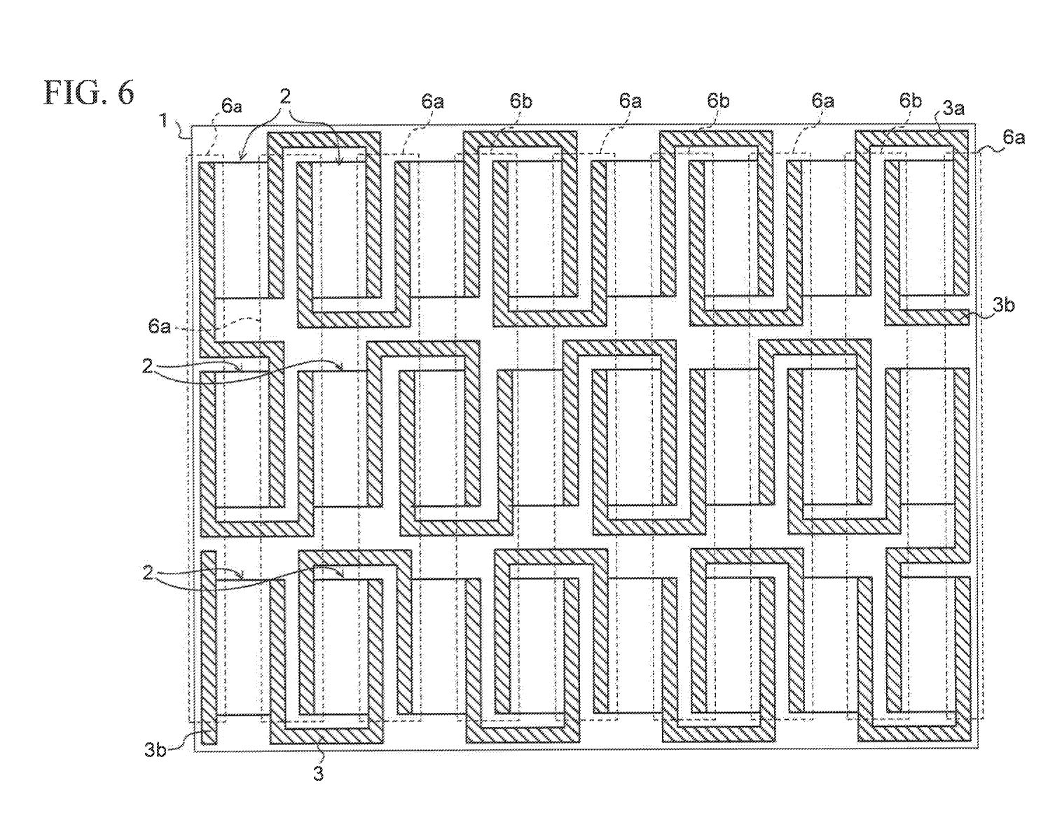

FIG. 6 is a plan view of a substrate and thermoelectric conversion elements formed thereon in a thermoelectric conversion module according to modification 1 of the first embodiment. Note that in FIG. 6, the same components as those in FIG. 2 are denoted by the same reference numerals, and detailed description thereof is omitted.

In modification 1, as depicted in FIG. 6, a plurality of thermoelectric conversion elements 2 are arranged on the substrate 1 in the length-wise direction and in the widthwise direction, and these thermoelectric conversion elements 2 are connected in series by the wirings 3a.

By arranging a plurality of thermoelectric conversion elements 2 on the substrate 1 in the lengthwise direction and in the widthwise direction as described, it may be possible to output higher voltage than the thermoelectric conversion module 10 in FIGS. 1 and 2.

### Modification 2

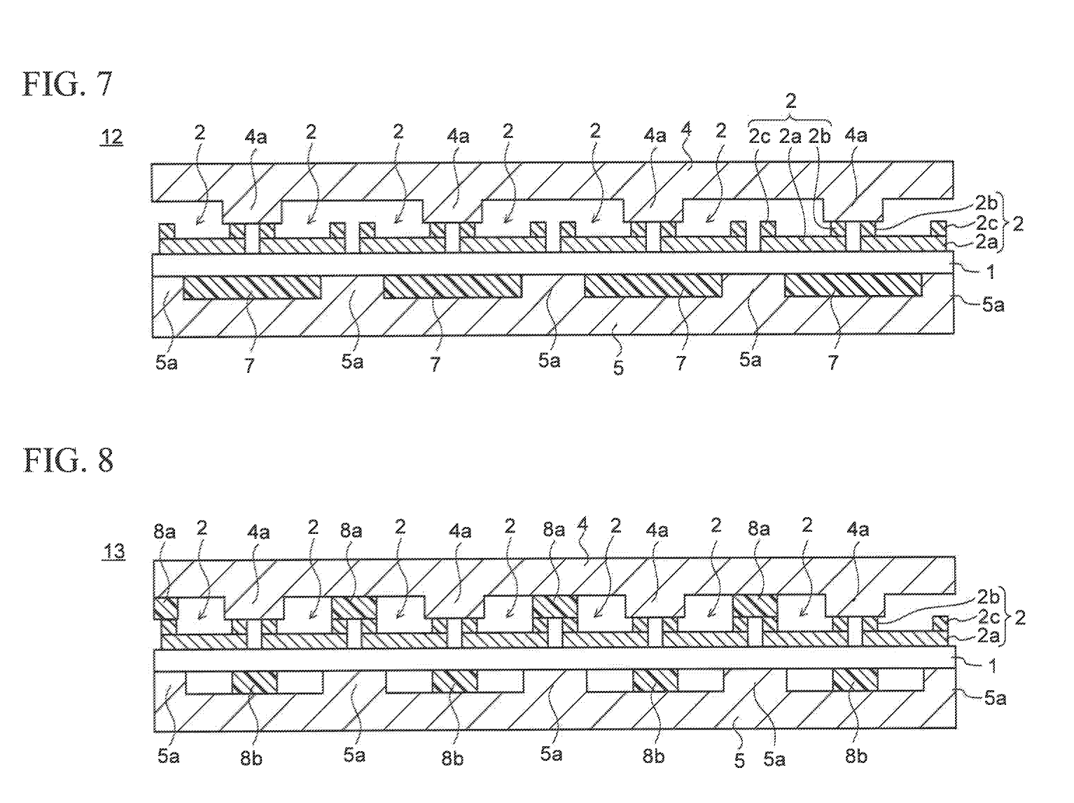

FIG. 7 is a cross-sectional view of a thermoelectric conversion module according to modification 2 of the first embodiment. Note that in FIG. 7, the same components as those in FIG. 3 are denoted by the same reference numerals.

In the thermoelectric conversion module 10 in FIG. 3, the substrate 1 is sandwiched and supported by the protruding portions 4a and 5a of the thermal conduction plates 4 and 5, and the positions of the protruding portions 4a do not coincide with the positions of the protruding portions 5a. For this reason, the application of a vertical stress to the thermal conduction plates 4 and 5 exerts a shear stress on the substrate 1 and possibly breaks the substrate 1.

In a thermoelectric conversion module 12 according to modification 2, as depicted in FIG. 7, a thermally insulative member 7 made of a material low in thermal conductivity is filled in the space between each pair of adjacent protruding portions 5a of the thermal conduction plate 5 disposed below the substrate 1. This allows the entire lower surface of the substrate 1 to be supported by the protruding portions 5a of the thermal conduction plate 5 and the thermally insulative members 7. Accordingly, the application of a large vertical stress to the thermal conduction plates 4 and 5 merely exerts a compressive stress on the substrate 1, so that the breakage of the substrate 1 is avoided.

Each of the thermally insulative members 7 is preferably formed of a material high in mechanical strength and low in thermal conductivity. As such a material, a polyimide resin, an epoxy resin, an ABS resin, and the like are available.

The thermally insulative members 7 are filled between the protruding portions 5a of the thermal conduction plate 5 by using the method below, for example. Specifically, first, the protruding portions 5a are formed on the upper surface of the thermal conduction plate 5 by pressing or the like, and the surface is subjected to insulating treatment. Thereafter, a resin as the material of the thermally insulative members 7 is applied on the upper surface of the thermal conduction plate 5 by spraying or printing, and then the resin on the protruding portions 5a is removed with a squeegee or the like, so that the resin is left between the protruding portions 5a. Subsequently, the resin is cured. As a result, the thermally insulative member is filled between the protruding portions 5a of the thermal conduction plate 5.

Note that while FIG. 7 describes an example where the thermally insulative members 7 are filled between the protruding portions 5a of the thermal conduction plate 5, the thermally insulative members 7 may instead be filled between the protruding portions 4a of the thermal conduction plate 4, or may be filled in both, i.e. between the protruding portions 4a of the thermal conduction plate 4 and between the protruding portions 5a of the thermal conduction plate 5.

### Modification 3

FIG. 8 is a cross-sectional view of a thermoelectric conversion module according to modification 3 of the first embodiment. Note that in FIG. 8, the same components as those in FIG. 3 are denoted by the same reference numerals, and detailed description thereof is omitted.

In a thermoelectric conversion module 13 according to modification 3, a thermally insulative member 8a of a size corresponding to that of each protruding portion 5a of the thermal conduction plate 5 is formed between each pair of adjacent protruding portions 4a of the thermal conduction plate 4. Moreover, a thermally insulative member 8b of a size corresponding to that of each protruding portion 4a of the thermal conduction plate 4 is formed between each pair of adjacent protruding portions 5a of the thermal conduction plate 5. These thermally insulative members 8a and 8b may be formed by printing, for example. This modification 3 may achieve the same advantageous effect as that of modification 2.

### Modification 4

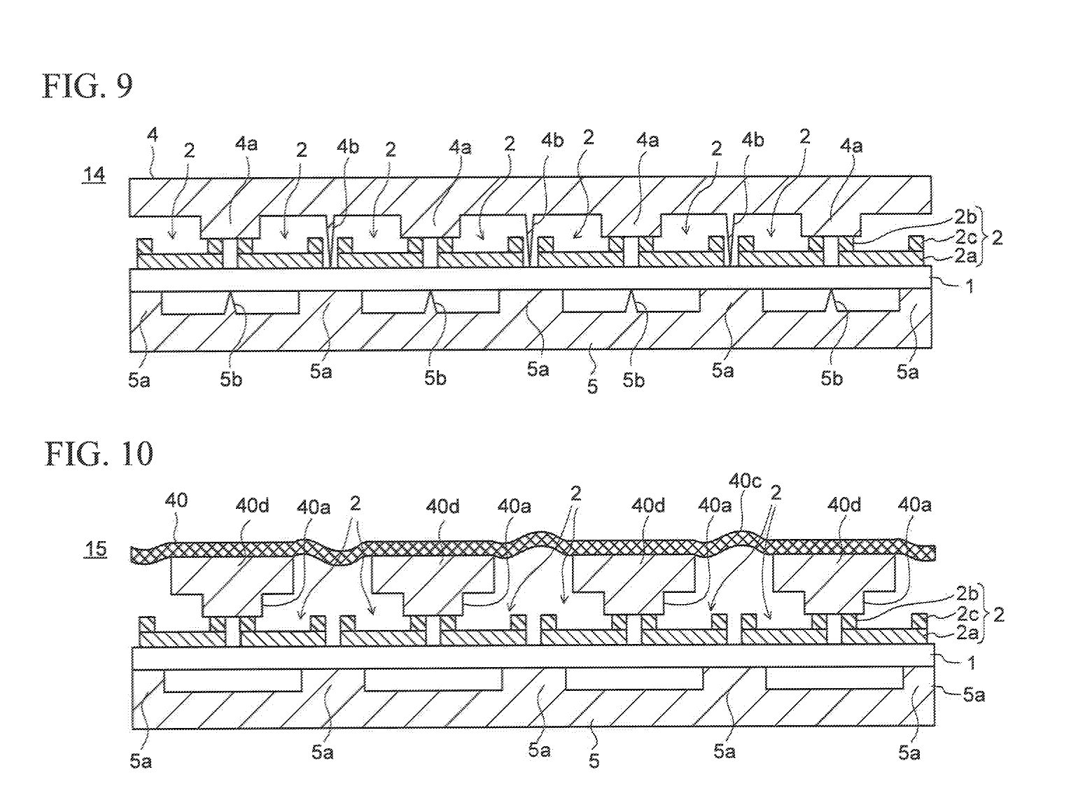

FIG. 9 is a cross-sectional view of a thermoelectric conversion module according to modification 4 of the first embodiment. Note that in FIG. 9, the same components as those in FIG. 3 are denoted by the same reference numerals, and detailed description thereof is omitted.

In a thermoelectric conversion module 14 according to modification 4, as depicted in FIG. 9, wedge-shaped protruding portions 5b are provided at portions of the thermal conduction plate 5 coinciding with the protruding portions 4a of the thermal conduction plate 4, respectively, and wedge-shaped protruding portions 4b are provided at portions of the thermal conduction plate 4 coinciding with the protruding portions 5a of the thermal conduction plate 5, respectively. The wedge-shaped protruding portions 4b and the wedge-shaped protruding portions 5b are each formed to have a narrow tip in order to reduce the thermal conduction between the substrate 1 and the portion in contact therewith.

These wedge-shaped protruding portions 4b and wedge-shaped protruding portions 5b may be formed along with the formation of the protruding portions 4a and the protruding portions 5a by pressing, for example. This modification 4, too, may achieve the same advantageous effect as that of modification 2.

### Modification 5

FIG. 10 is a cross-sectional view of a thermoelectric conversion module according to modification 5 of the first embodiment. Note that in FIG. 10, the same components as those, in FIG. 3 are denoted by the same reference numerals, and detailed description thereof is omitted.

A thermoelectric conversion module 15 according to modification 5 uses a thermal conduction plate 40 in place of the thermal conduction plate 4 in FIG. 3. This thermal conduction plate 40 includes: a plurality of heat blocks 40d with protruding portions 40a in contact with the high-temperature side electrodes 2b of the thermoelectric conversion elements 2; and a flexible thermal conduction sheet (heat spreader) 40c connecting these heat blocks 40d.

In the thermoelectric conversion module 10 in FIG. 3, the thermal conduction plate 4 and the substrate 1 differ from each other in coefficient of thermal expansion. Thus, as the temperature of the thermal conduction plate 4 becomes high, a stress is exerted between the thermal conduction plate 4 and the substrate 1 in a direction parallel to the substrate surface, and possibly breaks the bond between the thermal conduction plate 4 and the thermoelectric conversion elements 2. Breaking the bond between the thermal conduction plate 4 and the thermoelectric conversion elements 2 impairs the thermal conduction between the thermal conduction plate 4 and the thermoelectric conversion elements 2, and hence lowers the thermoelectric conversion efficiency.

In contrast, in the thermoelectric conversion module 15 of modification 5, the heat blocks 40d are connected by the flexible thermal conduction sheet 40c; thus, even when the heat blocks 40d undergo thermal expansion, the resultant stress is absorbed by the thermal conduction sheet 40c. Accordingly, the influence of the thermal expansion of the heat blocks 40d is not transferred to the thermoelectric conversion elements 2, so that the breakage of the bond between the heat blocks 40d and thermoelectric conversion elements 2 is avoided. Thereby, the reliability of the thermoelectric conversion module is improved.

Note that while the thermal conduction plate 40 including the heat blocks 40d and the thermal conduction sheet 40c is disposed on the high-temperature side in modification 5, a thermal conduction plate having a same structure may be used on the low-temperature side as well.

### Modification 6

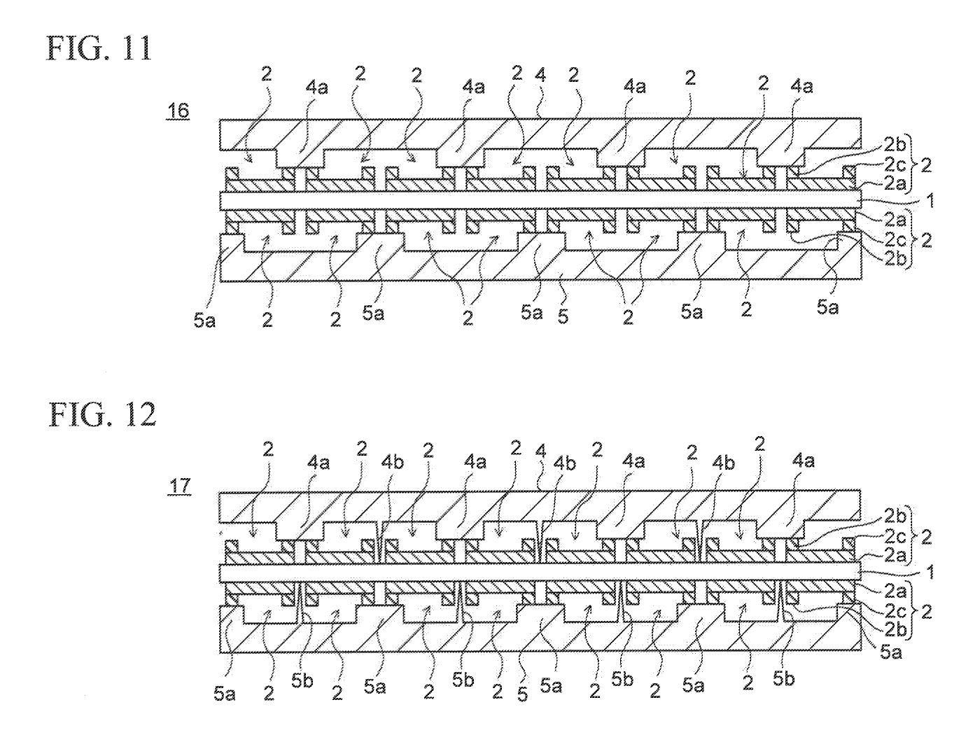

FIG. 11 is a cross-sectional view of a thermoelectric conversion module according to modification 6 of the first embodiment. Note that in FIG. 11, the same components as those in FIG. 3 are denoted by the same reference numerals, and detailed description thereof is omitted.

In a thermoelectric conversion module 16 according to modification 6, the thermoelectric conversion elements 2 are disposed on both surfaces of the substrate 1. The protruding portions 4a of the thermal conduction plate 4 are connected to the high-temperature side electrodes 2b of the thermoelectric conversion elements 2 disposed on the upper side of the substrate 1. The protruding portions 5a of the thermal conduction plate 5 are connected to the low-temperature side electrodes 2c of the thermoelectric conversion elements 2 disposed on the lower side of the substrate 1.

While the thermoelectric conversion elements 2 are disposed on one surface of the substrate 1 in the thermoelectric conversion module 10 in FIG. 3, the thermoelectric conversion elements 2 are disposed on both surfaces of the substrate 1 in the thermoelectric conversion module 16 of modification 6. Hence, the maximum output of the thermoelectric conversion module 16 per unit area is approximately twice that of the thermoelectric conversion module 10 in FIG. 3.

### Modification 7

FIG. 12 is a cross-sectional view of a thermoelectric conversion module according to modification 7 of the first embodiment. Note that in FIG. 12, the same components as those in FIG. 11 are denoted by the same reference numerals.

In a thermoelectric conversion module 17 according to modification 7, the thermoelectric conversion elements 2 are disposed on both, upper and lower surfaces of the substrate 1 as depicted in FIG. 12. Moreover, like modification 4 (see FIG. 9), the thermal conduction plate 4 has the wedge-shaped protruding portions 4b, and the thermal conduction plate 5 has the wedge-shaped protruding portions 5b. The wedge-shaped protruding portions 4b are in contact with the substrate 1 between the low-temperature side electrodes 2c of the thermoelectric conversion elements 2 on the upper side of the substrate 1. The wedge-shaped protruding portions 5b are in contact with the substrate 1 between the high-temperature side electrodes 2b of the thermoelectric conversion elements 2 on the lower side of the substrate 1.

In the thermoelectric conversion module 17 of modification 7, the thermoelectric conversion elements 2 are disposed on both surfaces of the substrate 1 like modification 6; accordingly, the maximum output per unit area may be twice that of the thermoelectric conversion, module 10 in FIG. 3. Moreover, in the thermoe1ectric conversion module 17 of modification 7, the thermal conduction plates 4 and 5 have the wedge-shaped protruding portions 4b and 5b; accordingly, the breakage of the substrate 1 due to the application of a vertical stress to the thermal conduction plates 4 and 5 is avoided.

### 2. Second Embodiment

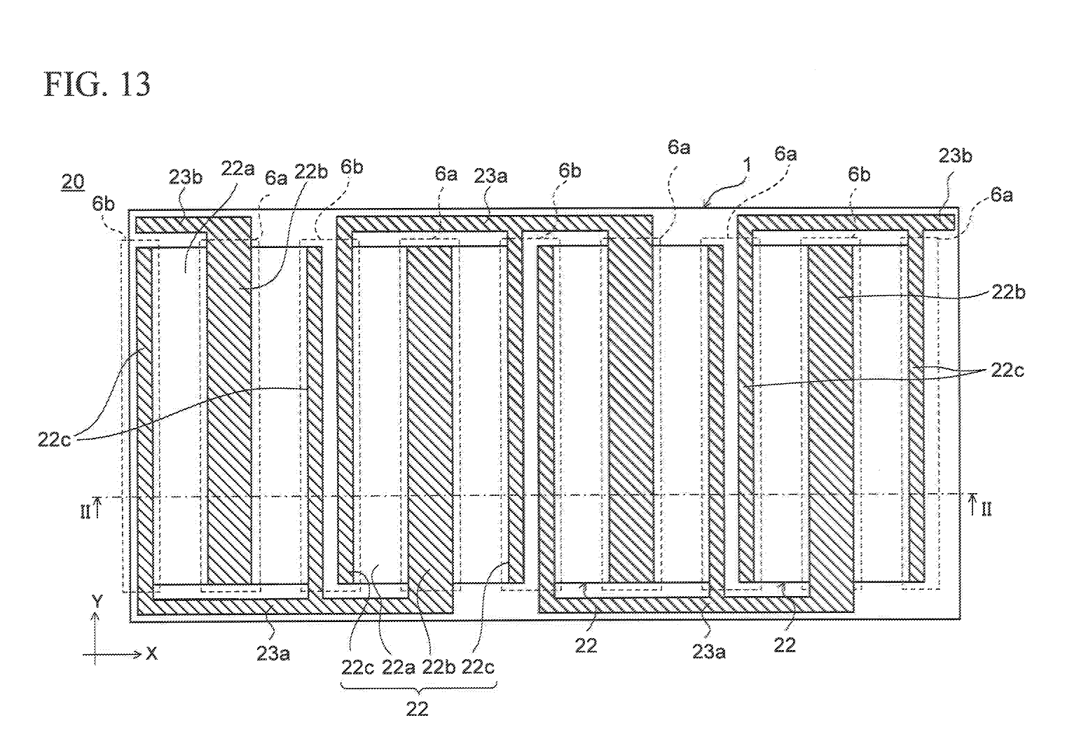

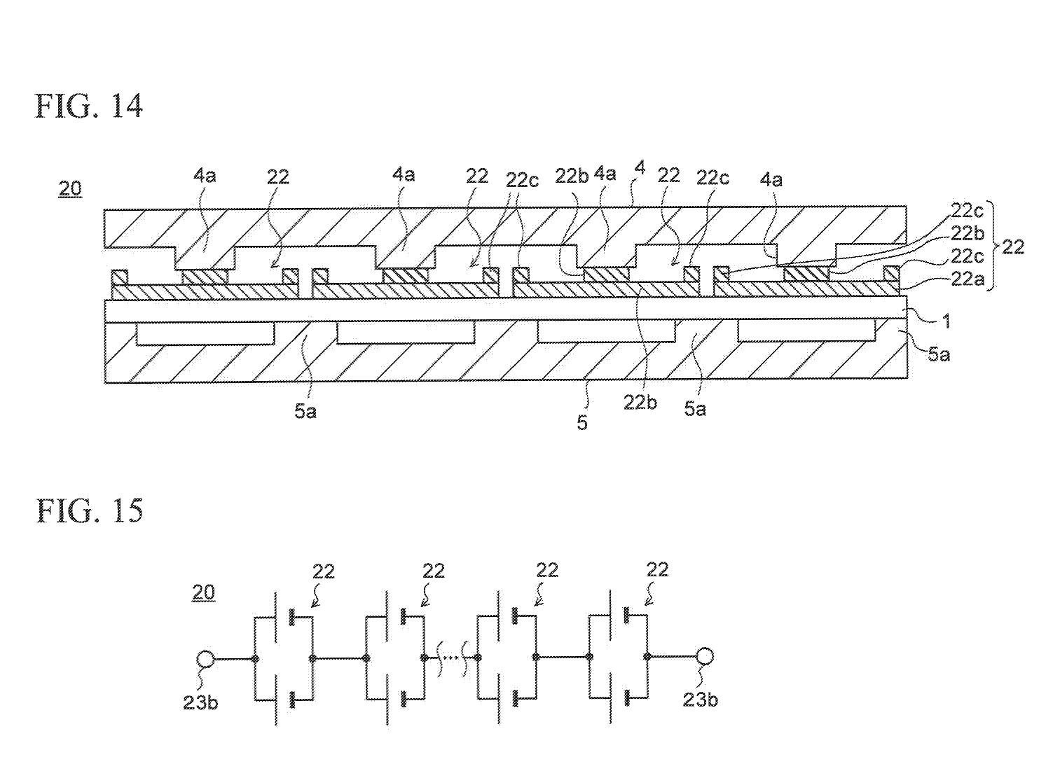

FIG. 13 is a plan view of a substrate on which thermoelectric conversion elements of a thermoelectric conversion module according to a second embodiment are formed. FIG. 14 is a cross-sectional view of that same thermoelectric conversion module. Note that FIG. 14 depicts a cross-sectional view taken along the II-II line of FIG. 13.

As depicted in FIG. 14, a thermoelectric conversion module 20 according to this embodiment has a structure in which an insulative substrate 1 with thermoelectric conversion elements 22 formed thereon is sandwiched by two thermal conduction plates 4 and 5.

A plurality of thermoelectric conversion material films 22a are disposed on the insulative substrate 1 at a fixed pitch in an in-plane direction. As depicted in FIG. 13, a high-temperature side electrode 22b extending in a Y direction is formed on a center portion of each thermoelectric conversion material film 22a. Moreover, low-temperature side electrodes 22c are formed respectively on both end portions of each thermoelectric conversion material film 22a in parallel with the high-temperature side electrode 22b. In other words, in this embodiment, a single thermoelectric conversion material film 22a is used to form a pair of thermoelectric conversion elements 22 that shares a single high-temperature side electrode 22b. The two low-temperature side electrodes 22c of this pair of thermoelectric conversion elements 22 are electrically connected to each other through a wiring 23a and further electrically connected to the high-temperature side electrode 22b of the adjacent right pair of thermoelectric, conversion elements 22 through the wiring 23a.

In the thermoelectric conversion module 20 in FIG. 13, the high-temperature side electrode 22b of the thermoelectric conversion element 22 disposed at the left end and the low-temperature side electrode 22c of the thermoelectric conversion element 22 disposed at the right end are connected respectively to extraction electrodes 23b through which to extract electric power.

FIG. 15 is an equivalent circuit diagram of the thermoelectric conversion module 20 according to this embodiment. As depicted in this FIG. 15, the thermoelectric conversion module 20 according to this embodiment has a structure in which two thermoelectric conversion elements 22 are connected in parallel to form a pair of thermoelectric conversion elements, and a plurality of pairs of thermoelectric conversion elements are connected in series between the pair of extraction electrodes 23b.

Like the first embodiment, the thermal conduction plates 4 and 5 are each formed of an aluminum plate with its surface subjected to insulating treatment, for example. As depicted in FIG. 14, the thermal conduction plate 4 has protruding portions 4a in contact with the high-temperature side electrodes 22b of the thermoelectric conversion elements 22, and the thermal conduction plate 5 has protruding portions 5a in contact with the back surface of the substrate 1 at areas coinciding with the low-temperature side electrodes 22c of the thermoelectric conversion elements 22. In FIG. 13, reference numerals 6a are the areas for the protruding portions 4a of the thermal conduction plate 4 to contact, and reference numerals 6b are the areas for the protruding portions 5a of the thermal conduction plate 5 to contact.

In the thermoelectric conversion module 20 according to this embodiment configured as above, the thermal conduction plate 4 is disposed on the high-temperature side, and the thermal conduction plate 5 is disposed on the low-temperature side. In this way, heat is transferred to the thermoelectric conversion material films 22a of the thermoelectric conversion elements 22 through the protruding portions 4a and 5a of the thermal conduction plates 4 and 5 and the insulative substrate 1, thereby causing a temperature difference in each thermoelectric conversion material film 22a in the in-plane direction (in a direction from the high-temperature side electrode 22b toward the low-temperature side electrode 22c). Accordingly, voltage is generated by the Seebeck effect between the high-temperature side electrode 22b and the low-temperature side electrode 22c. The voltage generated by each thermoelectric conversion element 22 may be extracted to the outside through the pair of extraction electrodes 23b.

In the thermoelectric conversion module 10 of the first embodiment, a plurality of thermoelectric conversion elements 2 are connected in series between a pair of extraction electrodes 3b as depicted in the equivalent circuit in FIG. 4. Thus, the thermoelectric conversion module 10 will not function as a thermoelectric conversion module in the event of a disconnection defect in even one of the thermoelectric conversion elements 2. In contrast, the thermoelectric conversion module 20 according to this embodiment whose equivalent circuit is illustrated in FIG. 15 functions as a thermoelectric conversion module even in the event of a disconnection defect in any one of the paired thermoelectric conversion elements 22. Accordingly, the manufacturing yield is improved, and further the reliability is improved as well.

Moreover, in the thermoelectric conversion module 20 according to this embodiment, each pair of thermoelectric conversion elements 22 shares one high-temperature side electrode 22b; thus, the resistance of the high-temperature side electrode 22b is small. Accordingly, the power loss by the high-temperature side electrode 22b is small.

Note that, having each two thermoelectric conversion elements 22 connected in parallel, the thermoelectric conversion module 20 according to this embodiment has an output voltage which is approximately ½ of the output voltage of the thermoelectric conversion module 10 of the first embodiment, if the thermoelectric conversion modules 10 and 20 have the same number of thermoelectric conversion elements. However, the maximum output current is approximately two times larger, and therefore the maximum output power is approximately equal.

A method of manufacturing the thermoelectric conversion module 20 according to this embodiment is basically the same as that of the first embodiment, except that the patterns of the electrodes 22b and 22c and the wirings 23a are different from those of the first embodiment. Thus, description of the method of manufacturing the thermoelectric conversion module 20 is omitted here.

Description is given below of the result of an observation on the properties of a thermoelectric conversion module 20 according to this embodiment which is actually manufactured.

A thermoelectric conversion module 20 is formed by forming 70 (35 pairs of) thermoelectric conversion elements 22 on a SiTiO₃ substrate 1 of a thickness of approximately 100 μm and by then attaching the thermal conduction plates 4 and 5. The thermoelectric conversion module 20 is of a substantially square shape with each side being approximately 15-mm long, and the thickness thereof is approximately 1 mm. Each thermoelectric conversion element 22 includes the thermoelectric conversion material film (a Nb-doped SrTiO₃ film: a Nb-STO film) 22a, the high-temperature side electrode 22b, and the low-temperature side electrodes 22c. The thickness of the thermoelectric conversion material film 22a is approximately 15 nm, and the lengths thereof in an X direction (widthwise direction) and a Y direction (lengthwise direction) in FIG. 13 are approximately 370 μm and approximately 15 mm, respectively. Moreover, the gap between the thermoelectric conversion material films 22a is approximately 30 μm, and the widths of the high-temperature side electrode 22b and the low-temperature side electrode 22c are approximately 60 μm and approximately 30 μm, respectively. Further, the two thermal conduction plates 4 and 5 are formed of aluminum, and their surfaces are subjected to anodic treatment.

When a temperature difference of 10° C. is given between the two thermal conduction plates 4 and 5, the open-circuit voltage and the maximum, output of this thermoelectric conversion module 20 are 0.3 V and 0.3 mW, respectively.

Modifications of the second embodiment are described below.

### (Modification 1)

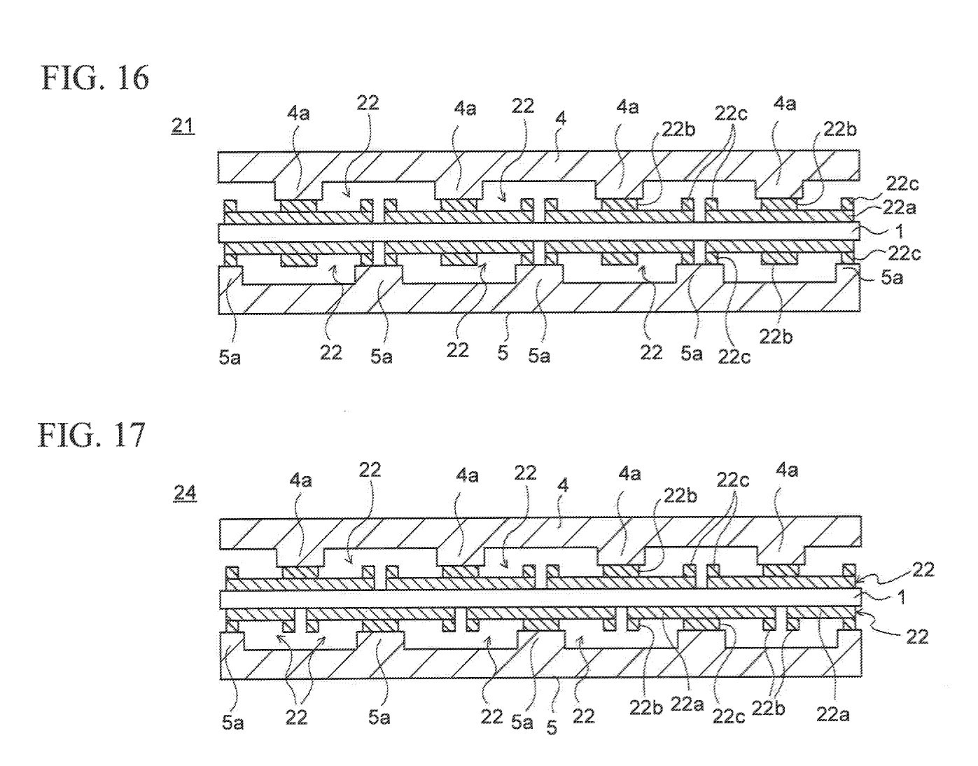

FIG. 16 is a cross-sectional view of a thermoelectric conversion module according to modification 1 of the second embodiment. Note that in FIG. 16, the same components as those in FIG. 14 are denoted by the same reference numerals, and detailed description thereof is omitted.

In a thermoelectric conversion module 21 according to modification 1, a plurality of pairs of thermoelectric conversion elements 22 are disposed on both surfaces of the substrate 1. Each pair of thermoelectric, conversion elements 22 includes a common thermoelectric conversion material film 22a, and a high-temperature side electrode 22b and low-temperature side electrodes 22c disposed on the upper (or lower) side of the thermoelectric conversion material film 22a. The high-temperature side electrode 22b is disposed at the center of the thermoelectric conversion material film 22a while the low-temperature side electrodes 22c are disposed on end portions of the thermoelectric conversion material film 22a.

The protruding portions 4a of the thermal, conduction plate 4 are connected to the high-temperature side electrodes 22b of the thermoelectric conversion elements 22 disposed on the upper side of the substrate 1, The protruding portions 5a of the thermal conduction plate 5 are connected to the low-temperature side electrodes 22c of the thermoelectric conversion elements 22 disposed on the lower side of the substrate 1.

While the thermoelectric conversion elements 22 are disposed on one surface of the substrate 1 in the thermoelectric conversion module 20 in FIG. 14, the thermoelectric conversion elements 22 are disposed on both surfaces of the substrate 1 in the thermoelectric conversion module 21 of modification 1. Hence, the maximum output of the thermoelectric conversion module 21 per unit area is approximately twice that of the thermoelectric conversion module 20 in FIG. 14.

### Modification 2

FIG. 17 is a cross-sectional view of a thermoelectric conversion module according to modification 2 of the second embodiment. Note that in FIG. 17, the same components as those in FIG. 14 are denoted by the same reference numerals.

In a thermoelectric conversion module 24 according to modification 2, a plurality of pairs of thermoelectric conversion elements are disposed on both surfaces of the substrate 1 like modification 1. In this modification 2, each pair of thermoelectric conversion elements 22 on the upper side of the substrate 1 is formed in the same way as modification 1. However, each pair of thermoelectric conversion elements 22 on the lower side of the substrate 1 is formed of a low-temperature side electrode 22c disposed at the center of the thermoelectric conversion material film 22a, and high-temperature side, electrodes 22b disposed on end portions of the thermoelectric conversion material film 22a. Thus, the thermoelectric conversion material films 22a on the lower side of the substrate 1 are disposed at positions shifted by a ½ pitch from the thermoelectric conversion material films 22a on the upper side of the substrate 1.

The protruding portions 4a of the thermal, conduction plate 4 are connected to the high-temperature side electrodes 22b of the thermoelectric conversion elements 22 disposed on the upper side of the substrate 1. The protruding portions 5a of the thermal conduction plate 5 are connected to the low-temperature side electrodes 22c of the thermoelectric conversion elements 22 disposed on the lower side of the substrate 1.

In the thermoelectric conversion module 24 of this modification 2 too, the maximum output per unit area is approximately twice that of the thermoelectric conversion module 20 in FIG. 14 since the thermoelectric conversion elements 22 are disposed on both surfaces of the substrate 1.

### Modification 3

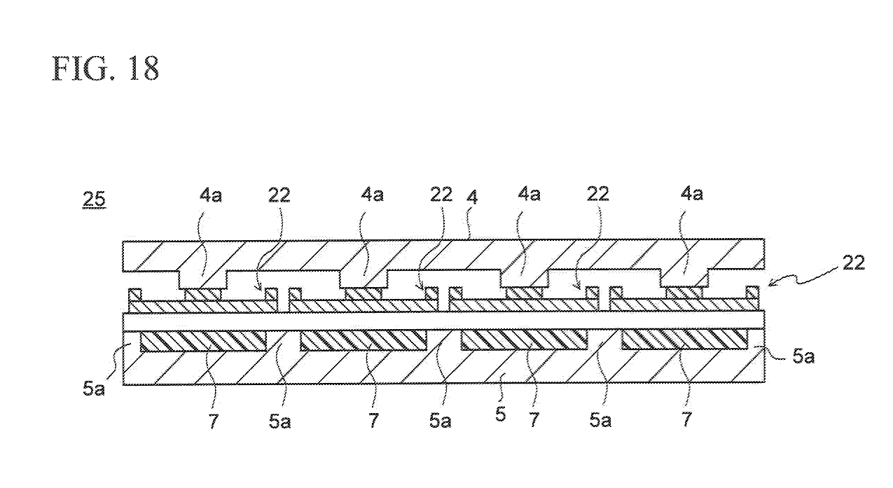

FIG. 1B is a cross-sectional view of a thermoelectric conversion module according to modification 3 of the second embodiment. Note that in FIG. 18, the same components as those in FIG. 14 are denoted, by the same reference numerals.

In a thermoelectric conversion module 25 according to modification 3, a thermally insulative member 7 made of a material low in thermal conductivity is filled in the space between each pair of adjacent protruding portions 5a of the thermal conduction plate 5 disposed below the substrate 1. This allows the entire lower surface of the substrate 1 to be supported by the thermally insulative members 7 and the protruding portions 5a of the thermal conduction plate 5. Accordingly, breakage of the substrate 1 is avoided even when a large vertical stress is applied to the thermal conduction plates 4 and 5.

### 3. Third Embodiment

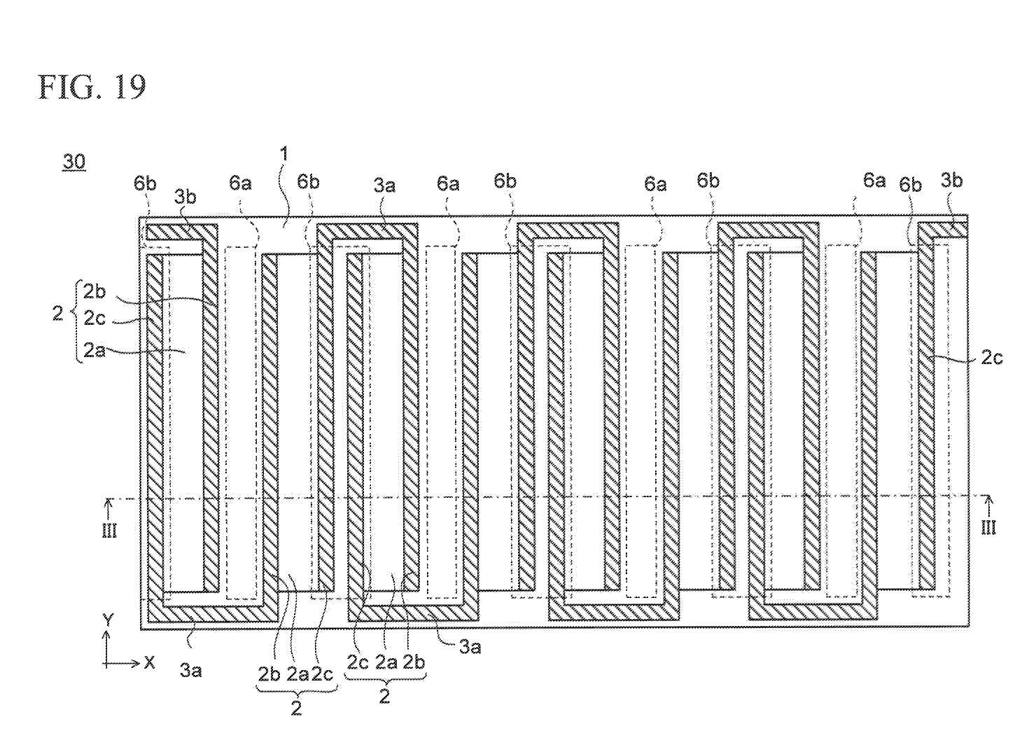

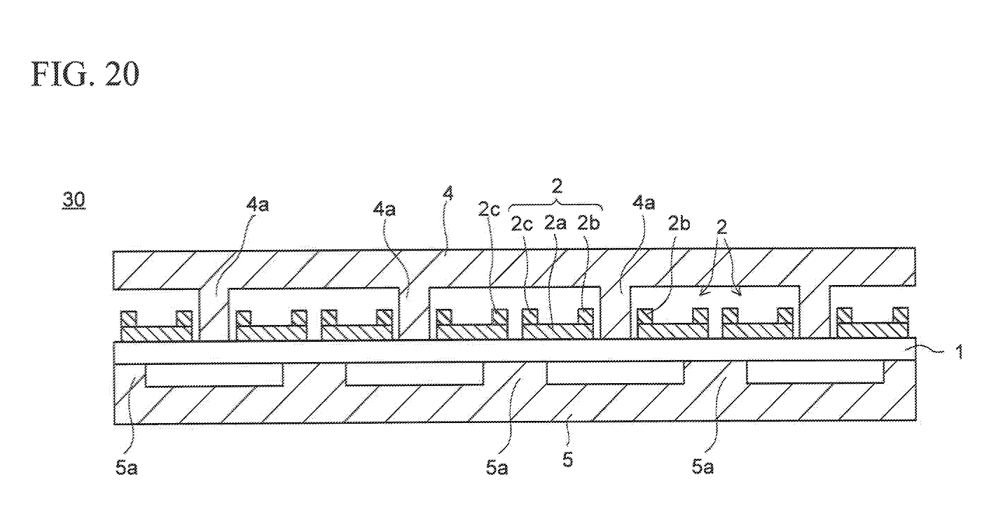

FIG. 19 is a plan view of a substrate on which thermoelectric conversion elements of a thermoelectric conversion module according to a third embodiment are formed. FIG. 20 is a cross-sectional view of that same thermoelectric conversion module. Note that FIG. 20 depicts a cross-sectional view taken along the III-III line of FIG. 19.

As depicted in FIGS. 19 and 20, the basic configuration of a thermoelectric conversion module 30 of this embodiment is substantially the same as that of the thermoelectric conversion module 10 in FIG. 3 (see the first embodiment). Thus, in FIGS. 19 and 20, the same components as those in FIG. 3 are denoted by the same reference numerals, and detailed description thereof is omitted.

In the thermoelectric conversion module 30 of this embodiment, as indicated by reference numerals 6a in FIG. 19, protruding portions 4a of a thermal conduction plate 4 are in contact with an insulative substrate 1 between high-temperature side electrodes 2b of thermoelectric conversion elements 2. In other words, in this embodiment, the protruding portions 4a of the thermal conduction plate 4 are in thermal contact with thermoelectric conversion material films 2a near the high-temperature side electrodes 2b through the insulative substrate 1.

Each protruding portion 4a of the thermal conduction plate 4 has its width (the length in an X direction in FIG. 19) set to approximately 20 μm, for example, and its length in the lengthwise direction (the length in a Y direction in FIG. 19) set to approximately 15 mm, for example, so as to be capable of sufficient thermal conduction with the insulative substrate 1. Moreover, the gap between the high-temperature side electrodes 2b of the adjacent thermoelectric conversion elements 2 is set to a gap (e.g. approximately 30 μm) wider than the protruding portion 4a so as to prevent contact between the protruding portion 4a and the high-temperature side electrodes 2b.

Protruding portions 5a of a thermal conduction plate 5 are in contact with the insulative substrate 1 at portions coinciding with low-temperature side electrodes 2c (portions indicated by reference numerals 6b in FIG. 19). In other words, the protruding portions 5a of the thermal conduction plate 5 are in thermal contact with the thermoelectric conversion material films 2a near the low-temperature side electrodes 2c through the insulative substrate 1.

The other features of the configuration of the thermoelectric, conversion module 30 of this embodiment are the same as those of the thermoelectric conversion module 10 of the first embodiment in FIGS. 1 to 3. Note that in this embodiment, the thermal conduction plates 4 and 5 (protruding portions 4a and 5a) make no contact with the thermoelectric conversion elements 2, and therefore the surfaces of the thermal conduction plates 4 and 5 are preferably not be subjected to insulating treatment.

The thermoelectric conversion module 30 configured as described above may achieve the same advantageous effects as those of the thermoelectric conversion module 10 in FIG. 3.

Moreover, in the thermoelectric conversion module 30 of this embodiment, the protruding portions 4a of the thermal conduction plate 4 make no contact with the high-temperature side electrodes 2b, unlike the thermoelectric conversion module 10 in FIG. 3. Thus, the thermoelectric conversion material films 2a and the electrodes 2b and 2c avoid receiving a mechanical stress from the protruding portions 4a, so that the thermoelectric conversion elements 2 are less likely to break even when a stress is applied from the outside through the thermal conduction plates 4 and 5. Accordingly, the reliability of the thermoelectric conversion module 30 is further improved.

Note that in this embodiment, like the first embodiment, a thermally insulative member may be disposed in the space between each pair of adjacent, protruding portions of the thermal conduction plates 4 and 5, and further the thermoelectric conversion elements 2 may be disposed on both surfaces of the substrate 1.

Description is given below of the result of an observation on the properties of a thermoelectric conversion module 30 according to this embodiment which is actually manufactured.

A thermoelectric conversion module 30 is formed by forming 70 thermoelectric conversion elements 2 on a SrTiO₃ substrate 1 of a thickness of approximately 100 μm and by then attaching the thermal conduction plates 4 and 5. This thermoelectric conversion module is of a substantially square shape with each side being approximately 15-mm long, and the thickness thereof is approximately 1 mm. The thickness of the thermoelectric conversion material film 2a included in each thermoelectric conversion element 2 is approximately 15 nm, and the lengths thereof in the X direction (widthwise direction) and the Y direction (lengthwise direction) in FIG. 19 are approximately 170 μm and approximately 15 mm, respectively. Moreover, the gap between the thermoelectric conversion elements 2 is approximately 30 μm. The two thermal conduction plates 4 and 5 are manufactured with copper, and their protruding portions 4a and 5a are joined to the substrate 1.

When a temperature difference of 10° C. is given between the two thermal conduction plates 4 and 5, the open-circuit voltage and the maximum output of this thermoelectric conversion module 30 are 0.6 V and 0.27 mW, respective1y.

### 4. Fourth Embodiment

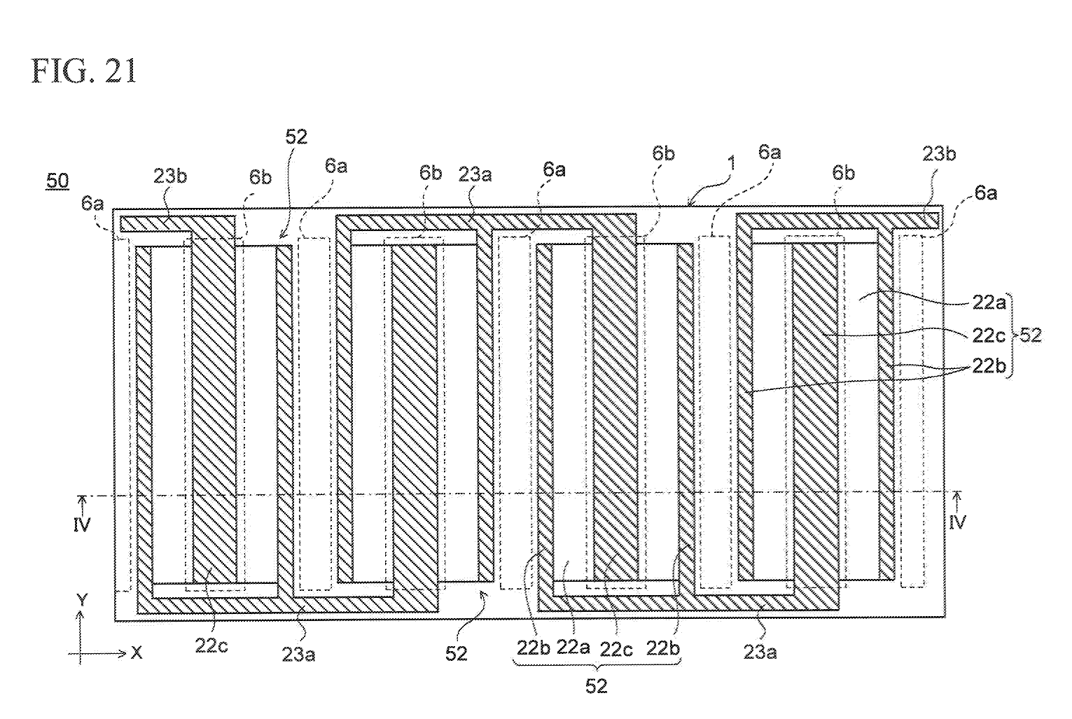

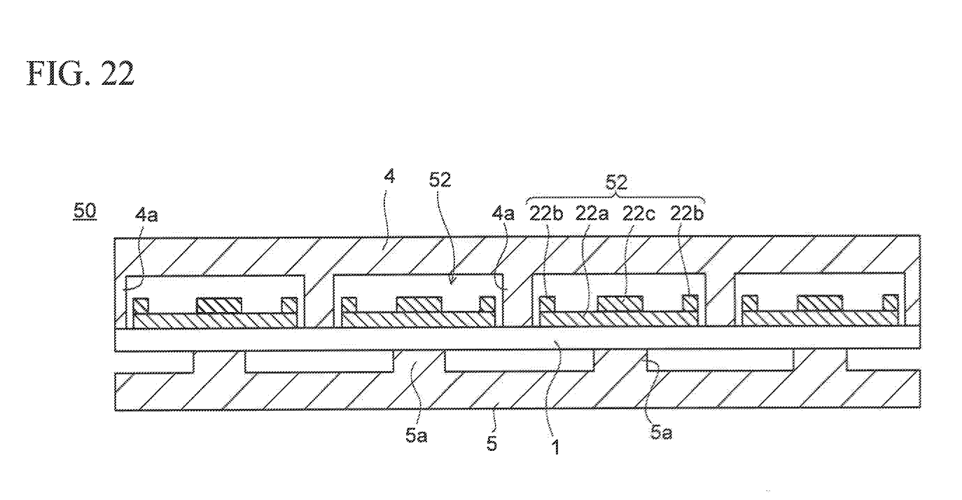

FIG. 21 is a plan view of a substrate on which thermoelectric conversion elements of a thermoelectric conversion module according to a fourth embodiment are formed. FIG. 22 is a cross-sectional view of that same thermoelectric conversion module. Note that FIG. 22 depicts a cross-sectional view taken along the IV-IV line of FIG. 21.

As depicted in FIGS. 21 and 22, the basic configuration of a thermoelectric conversion module 50 of this embodiment is the same as that of the thermoelectric conversion module 20 in FIG. 14 (see the second embodiment). Thus, in FIGS. 21 and 22, the same components as those in FIG. 14 are denoted by the same reference numerals, and detailed description thereof is omitted.

The thermoelectric conversion module 50 of this embodiment includes thermoelectric conversion elements 52 having a structure which is similar to that of the thermoelectric conversion elements 22 of the second embodiment (see FIG. 14). In each thermoelectric conversion element 52, however, the electrode formed on a center portion of the thermoelectric conversion material film 22a is the low-temperature side electrode 22c, and the electrodes formed on both end portions of the thermoelectric conversion material film 22a are the high-temperature side electrodes 22b. Thus, the high-temperature side electrodes 22b are disposed respectively along the facing sides of the adjacent thermoelectric conversion elements 52.

Protruding portions 4a of a thermal conduction plate 4 are each disposed between the high-temperature side electrodes 22b of a corresponding pair of adjacent thermoelectric conversion elements 52 and are in contact with an insulative substrate 1 at portions indicated by reference numerals 6a in FIG. 21. In other words, the protruding portions 4a of the thermal conduction plate 4 are in contact with the insulative substrate 1 between the high-temperature side electrodes 22b and are in thermal contact with the thermoelectric conversion material films 22a near the high-temperature side electrodes 22b through the insulative substrate 1.

Each protruding portion 4a of the thermal conduction plate 4 has its width (the length in an X direction in FIG. 21) set to approximately 20 μm, for example, and its length in the lengthwise direction (the length in a Y direction in FIG. 21) set to approximately 15 mm, for example. Moreover, the gap between the facing high-temperature side electrodes 22b of the adjacent thermoelectric conversion elements 22 is set to a gap (e.g. approximately 30 μm) wider than the protruding portion 4a so as to prevent contact between the protruding portion 4a and the high-temperature side electrodes 22b.

On the other hand, protruding portions 5a of a thermal conduction plate 5 are disposed at portions coinciding with the low-temperature side electrodes 22c and are in contact with the back surface of the insulative substrate 1 at portions indicated by reference numerals 6b in FIG. 21. Being in contact with the insulative substrate 1 near the low-temperature side electrodes 22c as described, the protruding portions 5a of the thermal conduction plate 5 are in thermal contact with the thermoelectric conversion material films 2a near the low-temperature side electrodes 22c through the insulative substrate 1.

The other features of the configuration of the thermoelectric conversion module 50 of this embodiment are the same as those of the thermoelectric conversion module 20 of the second embodiment in FIGS. 13 and 14. Note that in this embodiment, the thermal conduction plates 4 and 5 (protruding portions 4a and 5a) make no contact with the thermoelectric conversion elements 22, and therefore the surfaces of the thermal conduction plates 4 and 5 are preferably not to be subjected to insulating treatment.

The thermoelectric conversion module 50 configured as described above may achieve the same advantageous effects as those of the thermoelectric conversion module 20 in FIG. 14.

Moreover, in the thermoelectric conversion module 50, the protruding portions 4a of the thermal conduction plate 4 are in direct contact with the insulative substrate 1 without contacting the electrodes 22b, unlike the thermoelectric conversion module 20 in FIG. 14. Thus, the thermoelectric conversion material films 22a and the high-temperature side electrodes 22b avoid receiving a mechanical stress from the protruding portions 4a, so that the thermoelectric conversion elements 52 are less likely to break even when a stress is applied from the outside through the thermal conduction plates 4 and 5. Accordingly, the reliability of the thermoelectric conversion module 50 is further improved.

Note that in this embodiment, like the second embodiment, a thermally insulative member may be disposed in the space between, each pair of adjacent protruding portions 4a and 5a of the thermal conduction plates 4 and 5, and further the thermoelectric conversion elements 52 may be disposed on both surfaces of the substrate 1.

Description is given below of the result of an observation on the properties of a thermoelectric conversion module 50 according to this embodiment which is actually manufactured.

A thermoelectric conversion module 50 is formed by forming 70 (35 pairs of) thermoelectric conversion elements 52 on a SrTiO₃ substrate 1 of a thickness of approximately 100 μm and by then attaching the thermal conduction plates 4 and 5. This thermoelectric conversion module 50 is of a substantially square shape with each side being approximately 15-mm long, and the thickness thereof is approximately 1 mm. The thickness of the thermoelectric conversion material film (a Nb-doped SrTiO₃ film) 22a is approximately 15 nm, and the lengths thereof in the widthwise direction (the X direction in FIG. 21) and the lengthwise direction (the Y direction in FIG. 21) are approximately 370 μm and approximately 15 mm, respectively. The gap between the thermoelectric conversion elements 52 is approximately 30 μm, and the widths of the low-temperature side electrode 22c and the high-temperature side electrode 22b are approximately 60 μm and approximately 30 μm, respectively. The two thermal conduction plates 4 and 5 are formed of copper.

When a temperature difference of 10° C. is given between the two thermal conduction plates 4 and 5, the open-circuit voltage and the maximum output of this thermoelectric conversion module 50 are 0.3 V and 0.33 mW, respective1y.

### 5. Fifth Embodiment

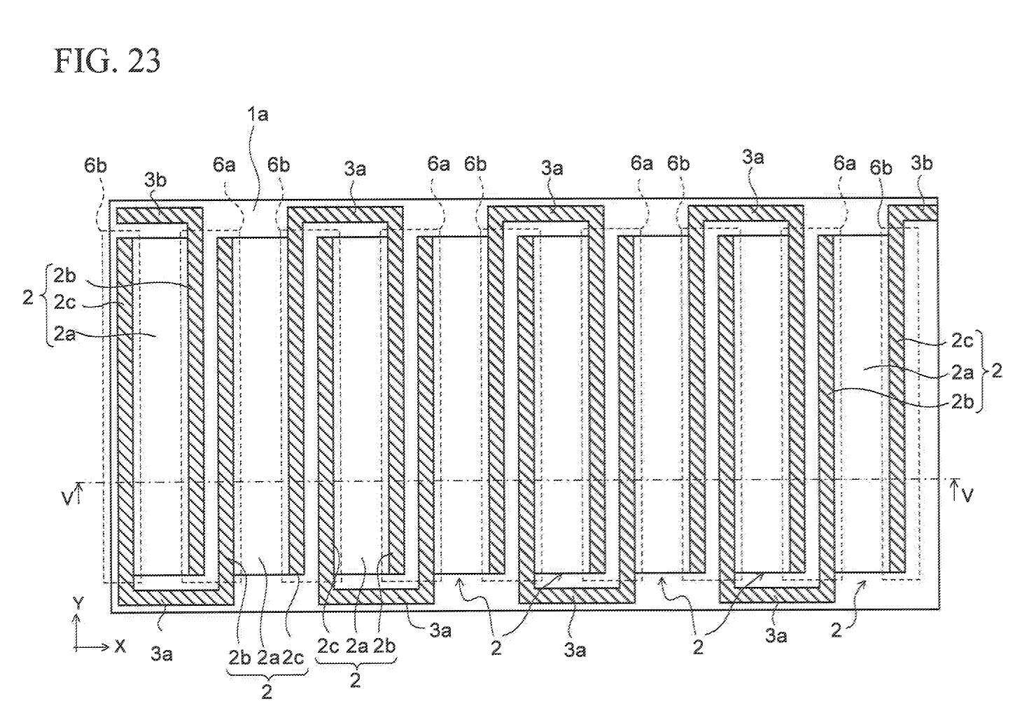

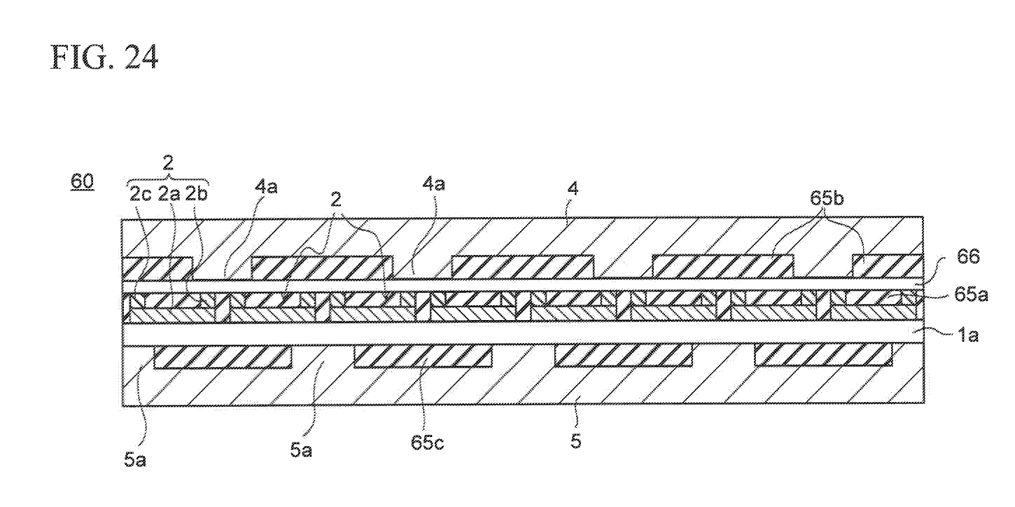

FIG. 23 is a plan view of a substrate on which thermoelectric conversion elements of a thermoelectric conversion module according to a fifth embodiment are formed. FIG. 24 is a cross-sectional view of that same thermoelectric conversion module. Note that FIG. 24 depicts a cross-sectional view taken along the V-V line of FIG. 23.

As depicted in FIGS. 23 and 24, the basic configuration of a thermoelectric conversion module 60 of this embodiment is substantially the same as that of the thermoelectric conversion module 10 in FIGS. 2 and 3 (see the first embodiment). Thus, in FIGS. 23 and 24, the same components as those in FIGS. 2 and 3 are denoted by the same reference numerals, and detailed description thereof is omitted.

In the thermoelectric conversion module 60 of this embodiment, an insulative substrate 1a is formed of a monocrystalline insulative material lower in thermal conductivity than SrTiO₃ such for example as zirconium oxide (ZrO₂) or cerium oxide (CeO₂). Moreover, thermally insulative members 65a, 65b, and 65c are filled in spaces inside the thermoelectric conversion module 60. Further, an insulating film 66 is provided between each thermoelectric conversion element 2 and a thermal conduction plate 4, and this insulating film 66 electrically insulates the thermal conduction plate 4 and the thermoelectric conversion element 2.

The other features of the configuration of the thermoelectric conversion module 60 are the same as those of the thermoelectric conversion module 10 of the first embodiment (see FIGS. 2 and 3).

The thermoelectric conversion module 60 of this embodiment configured as described above may achieve the same advantageous effects as those of the thermoelectric conversion module 10 of the first embodiment. Further, the thermal diffusion inside the insulative substrate 1a may be suppressed since the insulative substrate 1a is formed of a material lower in thermal conductivity than SrTiO₃ (such as ZrO₂ or CeO₂). This allows a larger temperature difference inside each thermoelectric conversion material film 2a. Accordingly, the power generation of each thermoelectric conversion element 2 may be further increased.

Moreover, in this embodiment, the thermally insulative members 65a, 65b, and 65c are filled in the spaces inside the thermoelectric conversion module 60; thus, the mechanical strength of the thermoelectric conversion module 60 is improved. Accordingly, breakage of the thermoelectric conversion module 60 due to an external force may be prevented.

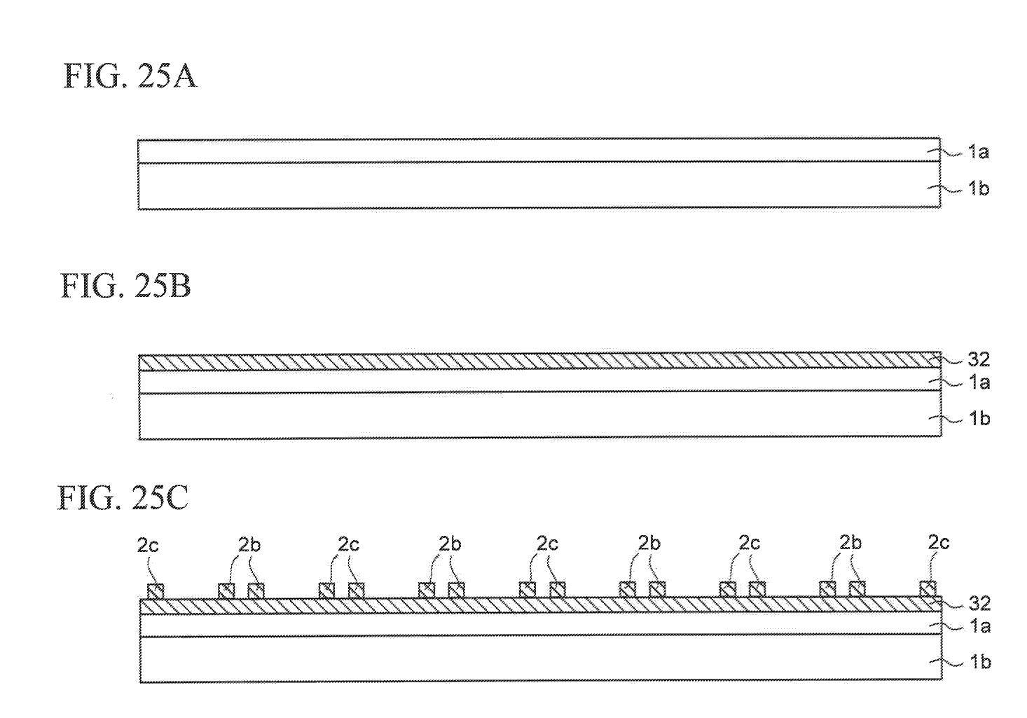

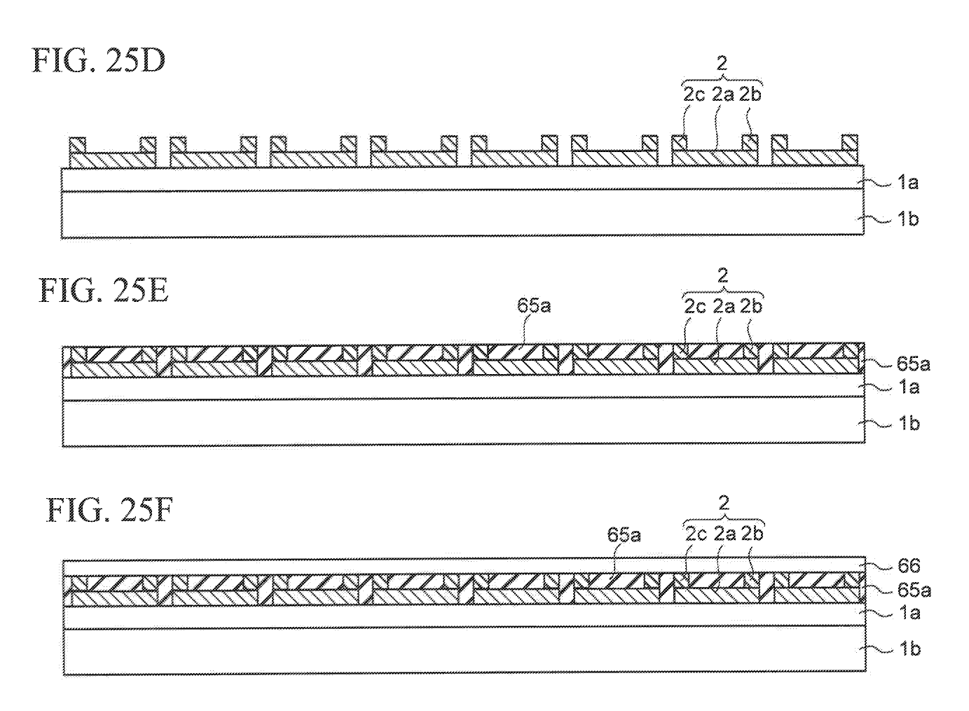

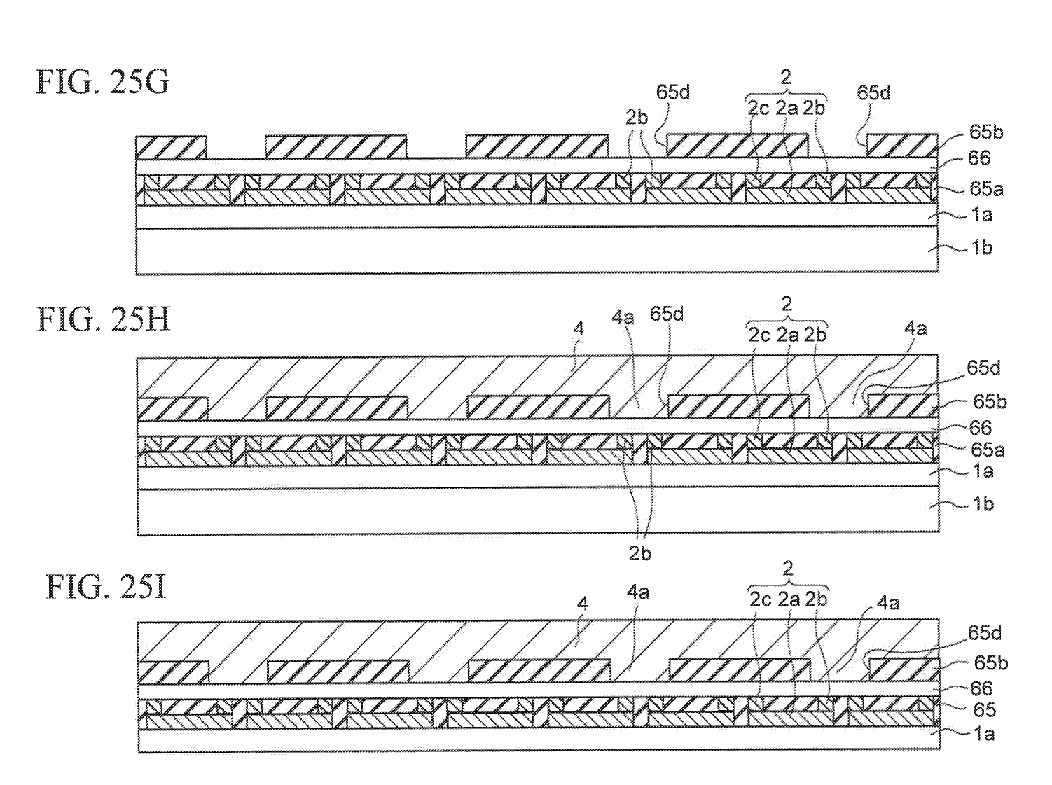

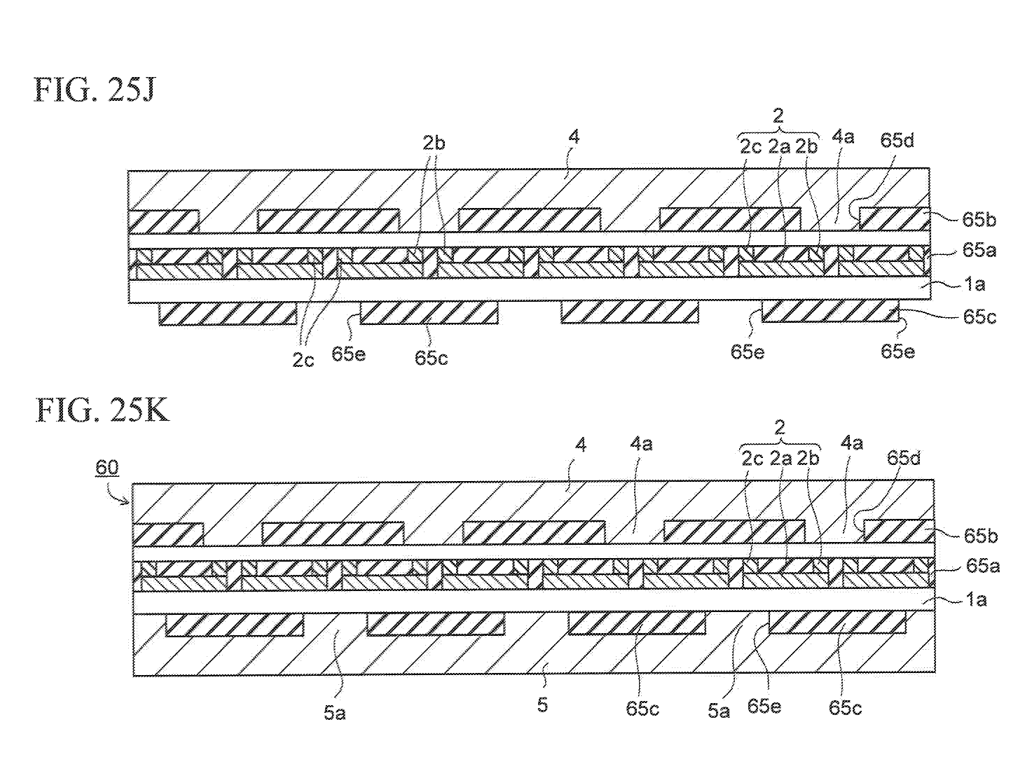

FIGS. 25A to 25K are cross-sectional views illustrating a method of manufacturing the thermoelectric conversion module 60 according to the fifth embodiment in a step-by-step manner.

First, as depicted in FIG. 25A, a monocrystalline silicon wafer 1b with a thickness of approximately 500 μm and with a surface orientation (100) is prepared. Then, ZrO₂ doped with Y (yttrium) by approximately 8 at % is deposited (epitaxially grown) to a thickness of approximately 5 μm on this silicon wafer 1b by sputtering to form, the insulative substrate 1a. Since ZrO₂ doped with Y has high toughness, the insulative substrate 1a may be made thin.

Note that the insulative substrate 1a may be formed of CeO₂ or may have a layered structure of ZrO₂ and CeO₂.

Next, as depicted in FIG. 25B, SrTiO₃ doped with niobium (Nb) (Nb-STO) by approximately 15 at % is deposited (epitaxially grown) to a thickness of approximately 50 nm on the insulative substrate 1a by sputtering to form an n-type thermoelectric conversion material film 32. Note that SrTiO₃ doped with no impurities may be deposited thinly (e.g. approximately 10 nm) prior to the deposition of Nb-STO. In this way, the crystallizability of the Nb-STO film is improved, and the thermoelectric conversion properties of the thermoelectric conversion material film 32 may therefore be improved further.

Next, as depicted in FIG. 25C, the high-temperature side electrodes 2b, the low-temperature side electrodes 2c, the wirings 3a (not depicted in FIG. 25C), and the extraction electrodes 3b (not depicted in FIG. 25C) are formed on the thermoelectric conversion material film 32. The high-temperature side electrodes 2b, the low-temperature side electrodes 2c, the wirings 3a, and the extraction electrodes 3b are formed preferably by following the same steps as those described with reference to FIG. 5B.

Next, as depicted in FIG. 25D, the thermoelectric conversion material film 32 is patterned to form the plurality of thermoelectric conversion elements 2 on the insulative substrate 1a, each of which includes a thermoelectric conversion material film 2a, a high-temperature side electrode 2b, and a low-temperature side electrode 2c. The thermoelectric conversion material film 32 is patterned preferably by following the same steps as those described with reference to FIG. 5C.

Next, as depicted in FIG. 25E, a resin such for example, as a polyimide resin, an epoxy resin, or an ABS resin is applied over the thermoelectric conversion elements 2 to form a resin, film, and this resin film is then polished until the upper surfaces of the electrodes 2b and 2c are exposed, to thereby form the thermally insulative member 65a. Note that the material of the thermally insulative member 65a is not limited to resin, and the thermally insulative member 65a may be formed of a non-resin material. In this embodiment, however, the thermally insulative member 65a is formed of a polyimide resin. The same applies also to the thermally insulative members 65b and 65c formed in steps described later.

Next, as depicted in FIG. 25F, alumina (Al₂O₃) is deposited to a thickness of approximately 100 nm on the thermally insulative member 65a, the high-temperature side electrodes 2b, and the low-temperature side electrodes 2c by sputtering to form the insulating film 66. The insulating film 66 may be formed of a material other than alumina, yet is preferably formed of an insulative material with good thermal conductivity so as not to impair the thermal conduction between the thermal conduction plate 4 and the thermoelectric conversion elements 2.

Next, as depicted in FIG. 25G, a polyimide resin film is formed on the insulating film 66, and the surface of this polyimide resin film is then polished and planarized to form a thermally insulative member 65b of a thickness of approximately 5 μm. Thereafter, portions of this thermally insulative member 65b above portions in which, the adjacent high-temperature side electrodes 2b face each other (portions indicated by reference numerals 6a in FIG. 23) are removed to form openings 65d through which the insulating film 66 is exposed.

Next, as depicted in FIG. 25H, a copper plating film of a thickness of 15 μm, for example, is formed on the thermally insulative members 65b and the insulating film 66, and the surface of this copper plating film is polished and planarized to form the thermal conduction plate 4. Note that the protruding portions 4a of the thermal conduction plate 4 are formed by the copper deposited inside the openings 65d.

Next, as depicted in FIG. 25I, the silicon wafer 1b on the lower surface of the insulative substrate 1a is removed by polishing or the like.

Next, as depicted in FIG. 25J, a polyimide resin film is formed on the lower surface of the insulative substrate 1a, and the surface of this polyimide resin film is then polished and planarized to form a thermally insulative member 65c of a thickness of approximately 5 μm. Thereafter, portions of this thermally insulative member 65c under portions in which the adjacent low-temperature side electrodes 2c face each other (portions indicated by reference numerals 6b in FIG. 23) are removed to form openings 65e.

Next, as depicted in FIG. 25K, a copper plating film of a thickness of approximately 15 μm, for example, is formed over the entire lower surface of the insulative substrate 1a, and this copper plating film is polished and planarized to form the thermal conduction plate 5. Note that the protruding portions 5a of the thermal conduction plate 5 are formed by the copper deposited inside the openings 65e.

Subsequently, the insulative substrate 1a is cut into each individual thermoelectric conversion module 60. As a result, the thermoelectric conversion module 60 of this embodiment is completed.

As described above, in the method of manufacturing the thermoelectric conversion module according to this embodiment, the insulative substrate 1a and the thermoelectric conversion elements 2 are formed on the silicon wafer 1b. Thus, the wafer size may be increased more easily than a case of using a monocrystalline SrTiO₃ wafer, hence allowing a larger number of thermoelectric conversion modules to be manufactured at a time. Accordingly, the manufacturing cost of the thermoelectric conversion module 60 may be reduced as compared to a case of using a monocrystalline SrTiO₃ substrate.

Note that while the silicon wafer 1b is completely removed in the process of manufacturing the thermoelectric conversion module 60 in the above-described example, the whole or part of the silicon wafer 1b may be left unremoved. In this way, the process of manufacturing the thermoelectric conversion module 60 may be further simplified. Nonetheless, the silicon wafer 1b is preferably removed as described above since silicon is higher in thermal conductivity than SrTiO₃.

Description is given below of the result of an observation on the properties of a thermoelectric conversion module 60 which is actually manufactured by using the method described above.

By using the method described above, an insulative substrate 1a of a thickness of approximately 5 μm made of ZrO₂ doped with Y is formed on a silicon wafer 1b of a thickness of approximately 500 μm, and 70 thermoelectric conversion elements 2 connected in series are formed on the insulative substrate 1a. Thereafter, the thermally insulative member 65a, the insulating film 66, the thermally insulative members 65b, and the thermal conduction plate 4 are formed. Then, the silicon wafer 1b is removed. Further, the thermally insulative members 65c and the thermal conduction plate 5 are formed on the lower side of the insulative substrate 1a. As a result, the thermoelectric conversion module 60 is obtained. This thermoelectric conversion module 60 is of a substantially square shape with each side being approximately 15-mm long, and the thickness thereof is approximately 1 mm. The thickness of the thermoelectric conversion material film 2a included in each thermoelectric conversion element 2 is approximately 50 nm, and the lengths thereof in an X direction (widthwise direction) and a Y direction (lengthwise direction) in FIG. 23 are approximately 170 μm and approximately 15 mm, respectively. Moreover, the gap between the thermoelectric conversion elements 2 is approximately 30 μm. Furthermore, the two thermal conduction plates 4 and 5 are formed of copper.

When a temperature difference of 10° C. is given between the two thermal conduction plates 4 and 5, the open-circuit voltage and the maximum output of this thermoelectric conversion module 60 are 0.6 V and 0.70 mW, respectively.

### 6. Sixth Embodiment

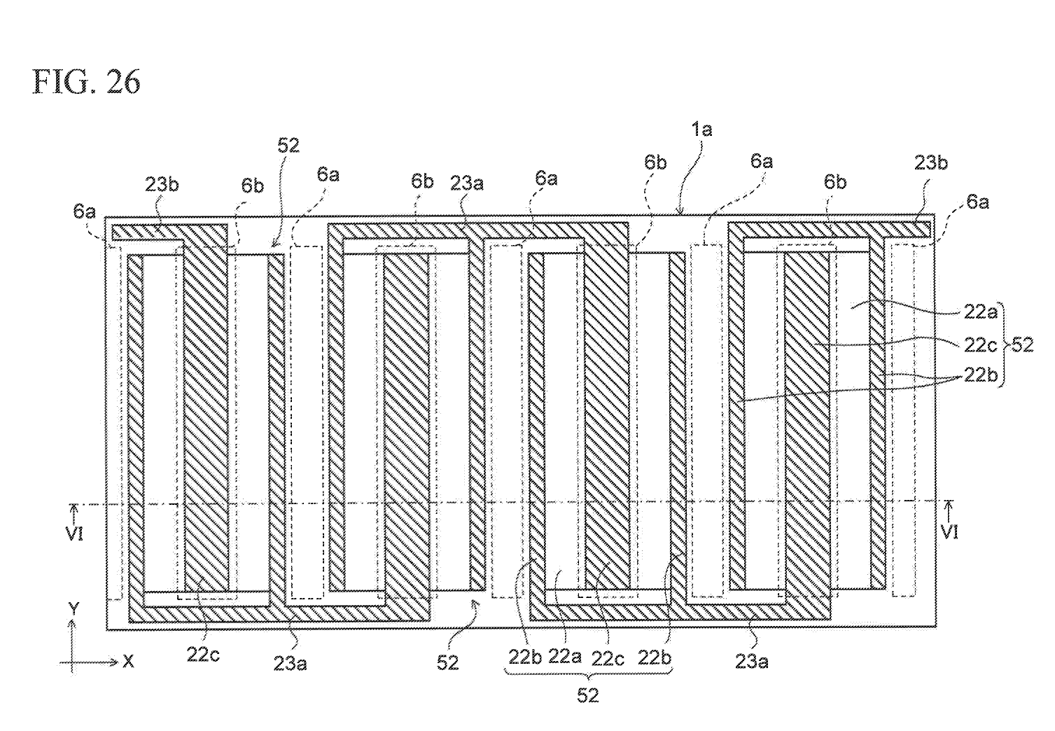

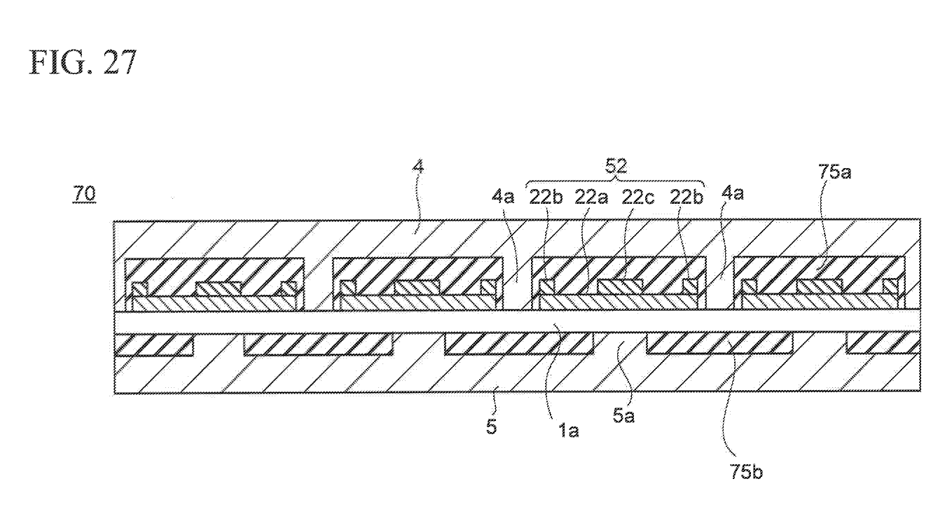

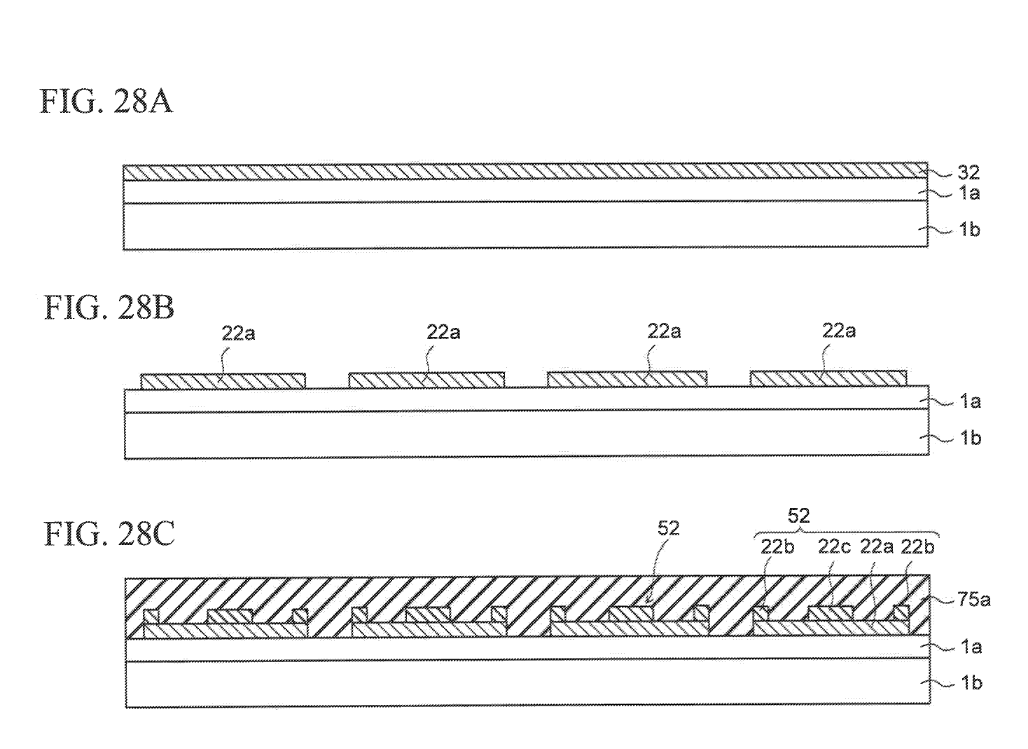

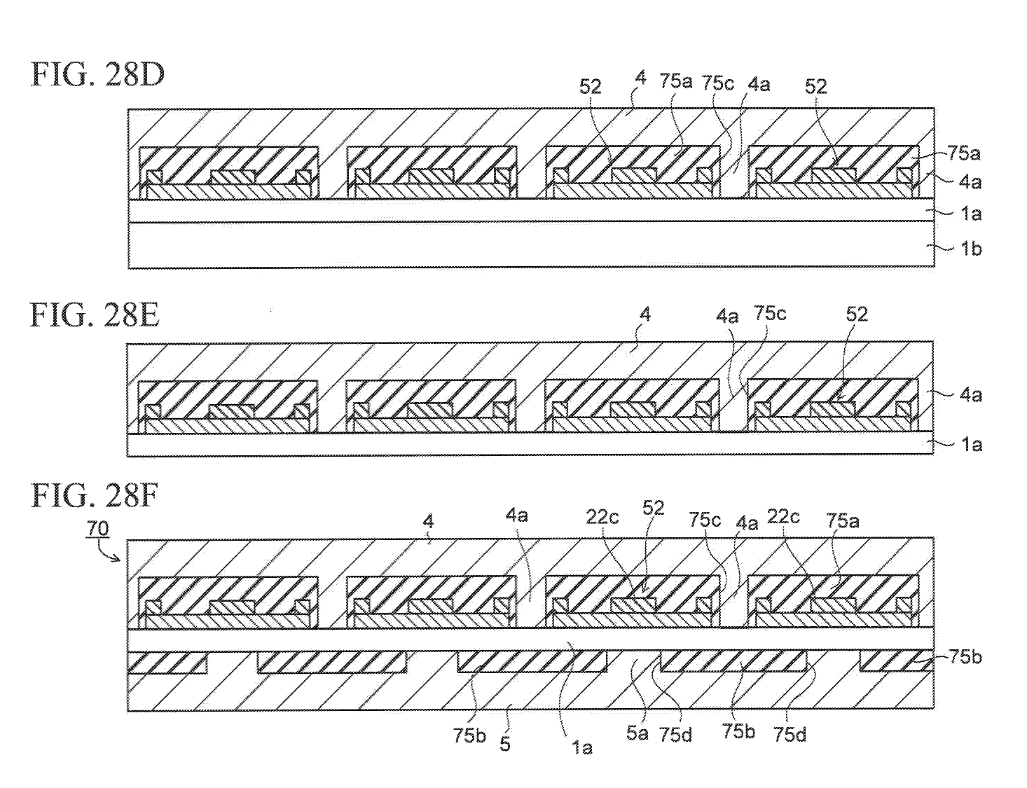

FIG. 26 is a plan view of a substrate on which thermoelectric conversion elements of a thermoelectric conversion module according to a sixth embodiment are formed. FIG. 27 is a cross-sectional view of that same thermoelectric conversion module. Note that FIG. 27 depicts a cross-sectional view taken along the VI-VI line of FIG. 26.

As depicted in FIGS. 26 and 27, the basic configuration of a thermoelectric conversion module 70 of this embodiment is substantially the same as that of the thermoelectric conversion module 50 in FIGS. 21 and 22 (see the fourth embodiment). Thus, in FIGS. 26 and 27, the same components as those in FIGS. 21 and 22 are denoted by the same reference numerals, and detailed description thereof is omitted.

In the thermoelectric conversion module 70 of this embodiment, an insulative substrate 1a is formed of a monocrystalline insulative material lower in thermal conductivity than SrTiO₃ such for example as ZrO₂ or CeO₂. Moreover, thermally insulative members 75a and 75b are filled in spaces inside the thermoelectric conversion module 70.

Note that the other features of the configuration of the thermoelectric conversion module 70 are the same as those of the thermoelectric conversion, module 50 of the fourth embodiment (see FIGS. 21 and 22), and therefore detailed description thereof is omitted.

The thermoelectric conversion module 70 configured as described above may achieve the same advantageous effects as those of the thermoelectric conversion module 50 of the fourth embodiment. Further, the thermal diffusion inside, the insulative substrate 1a may be suppressed since the insulative substrate 1a is formed of a material lower in thermal conductivity than STO (such as ZrO₂ or CeO₂). This allows a larger temperature difference inside each thermoelectric conversion material film 22a. Accordingly, the power generation of each thermoelectric conversion element 52 may be further increased.

Moreover, in the thermoelectric conversion module 70 of this embodiment, the thermally insulative members 75a and 75b are filled in the spaces inside the thermoelectric conversion module 70; thus, the mechanical strength of the thermoelectric conversion module 70 is high. Accordingly, the thermoelectric conversion module 70 is less likely to break even when an external force is applied.

FIGS. 28A and 28F are cross-sectional views illustrating a method of manufacturing the thermoelectric conversion module 70 according to the sixth embodiment in a step-by-step manner.

First, as depicted in FIG. 28A, a monocrystalline silicon wafer 1b with a thickness of approximately 500 μm and with a surface orientation (100) is prepared. Then, ZrO₂ doped with Y by approximately 8 at % is deposited (epitaxially grown) to a thickness of approximately 4 μm on this silicon wafer 1b by sputtering.

Thereafter, CeO₂ is deposited to a thickness of approximately 1 μm by sputtering. As a result, an insulative substrate 1a having a two-layer structure of a ZrO₂ layer and a CeO₂ layer is formed. In this embodiment, since the insulative substrate 1a includes a Y-ZrO₂ (ZrO₂ doped with Y) layer having high toughness, the insulative substrate 1a may be made thin. Moreover, since the CeO₂ layer is formed on the ZrO₂ layer, a thermoelectric conversion material (such as La-STO or Nb-STO) film 32 having good crystallizability may be formed on the insulative substrate 1a.

Next, SrTiO₃ doped with La by approximately 3 at % (La-STO) is deposited (epitaxially grown) to a thickness of approximately 50 nm on the insulative substrate 1a by sputtering to form the thermoelectric conversion material film 32.

Next, a resist pattern (not depicted) of a predetermined shape is formed on the thermoelectric conversion material film 32 by photolithography. Then, with this resist pattern as a mask, the thermoelectric conversion material film 32 is etched to form each thermoelectric conversion material film 22a in a predetermined pattern as depicted in FIG. 28B.

Next, as depicted in FIG. 28C, the high-temperature side electrodes 22b, the low-temperature side electrodes 22c, the wirings 23a (not depicted in FIG. 28C), and the extraction electrodes 23b (not depicted in FIG. 28C) are formed in their respective predetermined patterns by using a conductive material such for example as copper through the same method as that of the first embodiment (see FIG. 5B). As a result, the plurality of thermoelectric conversion elements 52 each including a thermoelectric conversion material film 22a, high-temperature side electrodes 22b, and a low-temperature side, electrode 22c are formed on the insulative substrate 1a.

Thereafter, a polyimide resin film is formed on the insulative substrate 1a and the thermoelectric conversion elements 52, and then this polyimide resin film is polished, and planarized to form a thermally insulative member 75a of a thickness of approximately 5 μm. By the above steps, the structure of FIG. 28C is completed.

Next, as depicted in FIG. 28D, portions of the thermally insulative member 75a above portions between the adjacent thermoelectric conversion material films 22a (portions indicated by reference numerals 6a in FIG. 26) are removed to form openings 75c through which the insulative substrate 1a is exposed. Thereafter, a copper plating film, for example, is formed to a thickness of approximately 15 μm on the openings 75c and the thermally insulative member 75a by plating. This copper plating film is then polished and planarized to become the thermal conduction plate 4.

Next, as depicted in FIG. 28E, the silicon wafer 1b below the insulative substrate 1a is removed by polishing, for example.

Next, as depicted in FIG. 28F, a polyimide resin film, for example, is formed on the back surface (lower surface in FIG. 32B) of the insulative substrate 1a, and the surface of this polyimide resin film is then polished and planarized to form a thermally insulative member 75b of a thickness of approximately 5 μm. Further, portions of this thermally insulative member 75b which coincide with the low-temperature side electrodes 22c (portions indicated by reference numerals 6b in FIG. 26) are removed to form openings 75d. Thereafter, a copper plating film, for example, is formed to a thickness of approximately 15 μm on the thermally insulative member 75b including the openings 75d. This copper plating film is polished and planarized to become the thermal conduction plate 5.

Subsequently, the insulative substrate 1a with the thermoelectric conversion elements 52 and the thermal conduction plates 4 and 5 formed thereon is cut into each individual module. As a result, the thermoelectric conversion module 70 of this embodiment is completed.

As described above, in the method of manufacturing the thermoelectric conversion module 70 of this embodiment as well, the insulative substrate 1a is formed on the silicon wafer 1b, and the thermoelectric conversion elements 52 are formed on the insulative substrate 1a, like the fifth embodiment. Thus, by increasing the size of the silicon wafer 1b, a larger number of thermoelectric conversion modules 70 may be manufactured at a time. Accordingly, the manufacturing cost of the thermoelectric conversion module 70 may be reduced.

Description is given below of the result of an observation on the properties of a thermoelectric conversion module 70 which is actually manufactured by using the method described above.

An insulative substrate 1a having a two-layer structure of a ZrO₂ layer and a CeO₂ layer is formed on a silicon wafer 1b of a thickness of 500 μm by forming a layer of ZrO₂ doped with Y by approximately 8 at % to a thickness of approximately 4 μm on the silicon wafer 1b and then forming a layer of CeO₂ to a thickness of approximately 1 μm on the ZrO₂ layer. Then, 70 (35 pairs of) thermoelectric conversion elements 52 are formed on this insulative substrate 1a. Thereafter, the thermally insulative member 75a and the thermal conduction plate 4 are formed. Then, the silicon wafer 1b is removed. Further, the thermally insulative members 75b and the thermal conduction plate 5 are formed. As a result, the thermoelectric conversion module 70 is formed.

This thermoelectric conversion module 70 is of a substantially square shape with each side being approximately 15-mm long, and the thickness thereof is approximately 1 mm. The thickness of each thermoelectric conversion material (Nb-STO) film 22a is approximately 50 nm, and the lengths thereof in the widthwise direction (an X direction, in FIG. 26) and the lengthwise direction (a Y direction in FIG. 26) are approximately 370 μm and approximately 15 mm, respectively. The gap between the thermoelectric conversion elements 52 is approximately 30 μm, and the widths of the low-temperature side electrode 22c and the high-temperature side electrode 22b are approximately 60 μm and approximately 30 μm, respectively. Moreover, the two thermal conduction plates 4 and 5 are formed of copper.

When a temperature difference of 10° C. is given between the two thermal conduction plates 4 and 5, the open-circuit voltage and the maximum output of this thermoelectric conversion module 70 are 0.3 V and 0.70 mW, respectively.

While the foregoing first to sixth embodiments have been described by taking an example where the thermal conduction plate 4 is disposed on the high-temperature side, and the thermal conduction plate 5 on the opposite side is disposed, on the low-temperature side, these embodiments are not limited to this example. The thermal conduction plate 4 may be disposed on the low-temperature side, and the thermal conduction plate 5 may be disposed on the high-temperature side. In this case, an electromotive force is generated in each thermoelectric conversion element in the direction opposite to that of the above example, and the voltage generated between the extraction electrodes of the thermoelectric conversion module is reversed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A thermoelectric conversion module comprising:
an insulative substrate;
a plurality of thermoelectric conversion material films disposed, with a gap therebetween on a first surface of the insulative substrate and made of any one of an n-type thermoelectric conversion material and a p-type thermoelectric conversion material;
a first electrode and a second electrode formed away from each other on each of the thermoelectric conversion material films;
a first thermal conduction member disposed on a side of the first surface of the insulative substrate and including a protruding portion in contact with the first electrodes; and
a second thermal conduction member disposed on a side of a second surface of the insulative substrate and including a protruding portion in contact with the second surface of the insulative substrate at an area coinciding with the second electrodes.

2. The thermoelectric conversion module according to claim 1, wherein
the first electrode is formed on a center portion of the corresponding thermoelectric conversion material film, while the second electrode is formed at each of positions sandwiching the first electrode on the thermoelectric conversion material film, and
the first electrode is connected to the second electrode on an adjacent one of the thermoelectric conversion material films,

3. A thermoelectric conversion module comprising:
an insulative substrate;
a plurality of thermoelectric conversion material films disposed with a gap therebetween on a first surface of the insulative substrate and made of any one of an n-type thermoelectric conversion material and a p-type thermoelectric conversion material;
a first electrode and a second electrode formed away from each other on each of the thermoelectric conversion material films;
a first thermal conduction member disposed on a side of the first surface of the insulative substrate and including a protruding portion, in contact with the insulative substrate between the first electrodes; and
a second thermal conduction member disposed on a side of a second surface of the insulative substrate and including a protruding portion in contact with the second surface of the insulative substrate at an area coinciding with the second electrodes.

4. The thermoelectric conversion module according to claim 3, wherein
the second electrode is formed on a center portion of the corresponding thermoelectric conversion material film, while the first electrode is formed at each of positions sandwiching the second electrode on the thermoelectric conversion, material film, and
the first electrode is connected to the second electrode on an adjacent one of the thermoelectric conversion material films.

5. The thermoelectric conversion module according to claim 1, wherein
the first electrode is formed along one side edge of the corresponding thermoelectric conversion material film, while the second electrode is formed along the other side edge of the thermoelectric conversion material film which is opposite to the one side edge, and
the first electrode is connected to the second electrode on the thermoelectric conversion material film located adjacently on one side, while the second electrode is connected to the first electrode on the thermoelectric conversion material film located adjacently on the other side.

6. The thermoelectric conversion module according to claim 1, wherein the thermoelectric conversion material films are formed of a conductive oxide mainly containing strontium titanate.

7. The thermoelectric conversion module according to claim 1, further comprising a thermally insulative member in a space between the protruding portions of at least one of the first thermal conduction member and the second thermal conduction member, the thermally insulative member having the same height as the protruding portions.

8. The thermoelectric conversion module according to claim 1, wherein an electrical conductivity of the thermoelectric conversion material films is between 1000 S/cm and 10000 S/cm, both inclusive.

9. The thermoelectric conversion module according to claim 1, wherein the thermoelectric conversion material films are monocrystalline films having an epitaxial relationship with the insulative substrate.

10. The thermoelectric conversion module according to claim 1, wherein the insulative substrate is made of a material lower in thermal conductivity than the thermoelectric conversion material films.

11. The thermoelectric conversion module according to claim 1, wherein the insulative substrate includes at least one of a layer mainly containing zirconium oxide and a layer mainly containing cerium oxide.

12. The thermoelectric conversion module according to claim 1, wherein the insulative substrate includes a layer made of silicon single crystals on a side of the surface opposite to the surface on which the thermoelectric conversion material films are formed.

13. The thermoelectric conversion module according to claim 1, wherein
thermoelectric conversion material films, first electrodes, and second electrodes, which are the same as those on the first, surface, are further provided on the second surface of the insulative substrate, and
the protruding portion of the second thermal conduction member is in contact with the second electrodes on the second surface.

14. The thermoelectric conversion module according to claim 1, wherein at least, one of the first thermal conduction member and the second thermal conduction member includes a plurality of heat blocks each including the protruding portion, and a flexible sheet connecting the heat blocks.

15. A method of manufacturing a thermoelectric conversion module, the method comprising:
forming a thermoelectric conversion material film on a first surface of an insulative substrate, the thermoelectric conversion material film being made of any one of an n-type thermoelectric conversion material and a p-type thermoelectric conversion material;
forming a first electrode and a second electrode away from each other on the thermoelectric, conversion material film;
patterning the thermoelectric conversion material film to form a plurality of thermoelectric conversion elements each including the thermoelectric conversion material film, the first electrode, and the second electrode;
disposing a first thermal conduction member on a side of the first surface of the insulative substrate, the first thermal conduction member including a protruding portion to be in contact with the first electrodes or the insulative substrate between the first electrodes, and disposing a second thermal conduction member on a side of a second surface of the insulative substrate, the second thermal conduction member including a protruding portion to be in contact with the second surface of the insulative substrate at an area coinciding with the second electrodes.

16. The method of manufacturing a thermoelectric conversion module according to claim 15, wherein
the insulative substrate is made of an insulative oxide mainly containing strontium titanate, and
the thermoelectric conversion material film is formed by epitaxially growing a conductive oxide on the insulative substrate, the conductive oxide mainly containing strontium titanate.

17. A method of manufacturing a thermoelectric conversion module, the method comprising:
forming an insulative substrate on a silicon wafer by epitaxially growing an insulative material thereon, the silicon wafer being made of silicon single crystals;
forming a thermoelectric conversion material film on the insulative substrate, the thermoelectric conversion material film being made of any one of an n-type thermoelectric conversion material and a p-type thermoelectric conversion material;
forming first electrodes and second electrodes away from each other on the thermoelectric conversion material film;
patterning the thermoelectric conversion material film to form a plurality of thermoelectric conversion elements including the thermoelectric conversion material films, the first electrodes, and the second electrodes;
forming a first thermal conduction member on the thermoelectric conversion elements, the first, thermal conduction member including a protruding portion to be in thermal contact with the thermoelectric conversion material films near the first electrodes;
removing the silicon wafer; and
forming a second thermal conduction member including a protruding portion to be in contact with a lower surface of the insulative substrate at an area coinciding with the second electrodes, wherein
the insulative substrate is formed of a material lower in thermal conductivity than the thermoelectric conversion material film.
